(19) United States
(12) Patent Application Publication
(10) Pub. No.: US 2008/0073750 A1
(43) Pub. Date: Mar. 27, 2008

(54) Semiconductor Storage Apparatus and Method for Manufacturing the Same

(76) Inventor: Hiroyuki KANAYA, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/858,777

(22) Filed: Sep. 20, 2007

(30) Foreign Application Priority Data
Sep. 21, 2006 (JP) P2006-256268

(51) Int. Cl. H01L 29/92; H01L 21/02

(52) U.S. Cl. 257/532; 438/3; 257/E29.342; 257/E21.008

(57) ABSTRACT

According to an aspect of the present invention, there is provided a semiconductor storage apparatus including: a semiconductor substrate; and a ferroelectric capacitor including: a bottom electrode disposed above the semiconductor substrate, a ferroelectric layer disposed on the bottom electrode, and a top electrode disposed on the ferroelectric layer. The ferroelectric capacitor includes: a first sidewall portion located on a position where the top electrode is in contact with the ferroelectric layer, and a second sidewall portion located above the first sidewall portion. The first sidewall portion forms a first angle with a top face of the ferroelectric layer. The second sidewall portion forms a second angle with the top face. The first angle is larger than the second angle.

### CROSS-REFERENCE TO RELATED APPLICATIONS

The entire disclosure of Japanese Patent Application No. 2006-256268 filed on Sep. 21, 2006 including specification, claims, drawings and abstract is incorporated herein by reference in its entirety.

### BACKGROUND OF THE INVENTION

1. Field of the Invention

An aspect of the present invention relates to a semiconductor storage apparatus and a method for manufacturing the semiconductor storage apparatus, and more particularly to a semiconductor storage apparatus having a small capacitor leakage and a method for manufacturing the semiconductor storage apparatus.

2. Description of the Related Art

With the advancement of the integration of ferroelectric memories (FeRAMs), it has become indispensable to form ferroelectric capacitors by carrying out Single-Mask Photo-Engraving Process (hereunder sometimes referred to as a “1-Mask-1-PEP”) to perform collective patterning processing. However, in such a ferroelectric capacitor (hereunder sometimes referred to as a “1-Mask-FeRAM”), a volatility of a ferroelectric capacitor material, particularly, a volatility of an electrode material formed by a noble metal such as platinum (Pt) or iridium (Ir) is remarkably poor. In the collectively processing capacitor formation through a reactive ion etching (RIE) process, therefore, there is a problem in that a residue is formed on a sidewall of a capacitor and a capacitor leakage is generated.

For a semiconductor integrated circuit contains a material that is rarely etched, such as Pt, Ru, Ir, PZT or HfO₂, there have been disclosed an effective technique for etching the material so that a sidewall of the etched material becomes substantially vertical (for example, see U.S. Pat. No. 6,835,665).

Also, there have already been disclosed improved steps of depositing a top electrode and etching a capacitor and a new cap oxide film depositing method for removing interface damages of a top electrode and of a ferroelectric layer sidewall portion, and a 1.6 V operational 0.18 micron 1T1C type FRAM having a smart card embedded which is mass productive and has a high reliability provided by applying the same (for example, see J. H. Kim et al., “Quality Assured Mass Productive 1.6V Operational 0.18 μm 1T1C FRAM Embedded Smart Card with Advanced Integration Technologies against Defectives”, 2005 International Electron Device Meeting, The Institute of Electrical and Electronic Engineers, Session 35-6, p. 879-882).

### SUMMARY OF THE INVENTION

According to an aspect of the present invention, there is provided a semiconductor storage apparatus including: a semiconductor substrate; and a ferroelectric capacitor including: a bottom electrode that is disposed above the semiconductor substrate, a ferroelectric layer that is disposed on the bottom electrode, and a top electrode that is disposed on the ferroelectric layer; wherein the ferroelectric capacitor includes: a first sidewall portion that is located on a position where the top electrode is in contact with the ferroelectric layer, and a second sidewall portion that is located above the first sidewall portion; wherein the first sidewall portion forms a first angle with a top face of the ferroelectric layer; wherein the second sidewall portion forms a second angle with the top face; and wherein the first angle is larger than the second angle.

According to another aspect of the present invention, there is provided a semiconductor storage apparatus including: a semiconductor substrate; and a ferroelectric capacitor including: a bottom electrode that is disposed above the semiconductor substrate, a ferroelectric layer that is disposed on the bottom electrode, and a top electrode that is disposed on the ferroelectric layer; wherein the ferroelectric capacitor includes: a first sidewall portion that is located on a position where the ferroelectric layer is in contact with the bottom electrode, and a second sidewall portion that is located on a position where the ferroelectric layer is in contact with the top electrode; wherein the first sidewall portion forms a first angle with a top face of the bottom electrode; wherein the second sidewall portion forms a second angle with the top face; and wherein the first angle is larger than the second angle.

According to still another aspect of the present invention, there is provided a method for manufacturing a semiconductor storage apparatus including: forming a source diffusion layer and a drain diffusion layer on a semiconductor substrate; forming an interlayer insulating film on the semiconductor substrate, on the source diffusion layer and on the drain diffusion layer; forming a bottom electrode on the interlayer insulating film; forming a ferroelectric layer on the bottom electrode; forming a top electrode on the ferroelectric layer; forming a hard mask having a lower etching-selectivity than the top electrode on the top electrode; and collectively processing the top electrode, the ferroelectric layer and the bottom electrode by performing an etching process including: a first etching process using a chloric gas or an inert gas as an etching gas.

According to still another aspect of the present invention, there is provided a semiconductor storage apparatus including: a semiconductor substrate; and a ferroelectric capacitor including: a bottom electrode that is disposed above the semiconductor substrate, a ferroelectric layer that is disposed on the bottom electrode, and a top electrode that is disposed on the ferroelectric layer; wherein the ferroelectric capacitor includes: a first sidewall portion that is located on a position where the bottom electrode is in contact with the ferroelectric layer, a second sidewall portion that is located on a position where the ferroelectric layer is in contact with the top electrode, and a third sidewall portion that is located above the second sidewall portion; wherein the first sidewall portion forms a first angle with a top face of the semiconductor substrate; wherein the third sidewall portion forms a third angle with the top face; and wherein the first angle is larger than the third angle.

### BRIEF DESCRIPTION OF THE DRAWINGS

Embodiment may be described in detail with reference to the accompanying drawings, in which:

FIG. 1 is a view showing a typical sectional structure of a semiconductor storage apparatus according to a first embodiment;

FIG. 2 is a chart showing a relationship between a capacitor leakage current and an angle ratio β′/α in the semiconductor storage apparatus according to the first embodiment;

FIG. 3 is a view showing a typical sectional structure of a semiconductor storage apparatus according to a first variant of the first embodiment;

FIG. 4 is a chart showing a relationship between a capacitor leakage current and an angle ratio β′/α in the semiconductor storage apparatus according to the first variant of the first embodiment;

FIG. 5 is a chart showing a relationship between a capacitor leakage current and a thickness ration A/B (a thickness A of a hardmask/a thickness B of a top electrode) in the semiconductor storage apparatus according to the first embodiment;

FIG. 6 is a view showing a typical sectional structure of a semiconductor storage apparatus according to a second variant of the first embodiment;

FIG. 7 is a view showing a typical sectional structure including the formation of a wiring electrode of the semiconductor storage apparatus according to the first embodiment;

FIG. 8 is a view showing a typical sectional structure of a semiconductor storage apparatus according to a second embodiment;

FIG. 9 is a view showing a typical sectional structure of a semiconductor storage apparatus according to a first variant of the second embodiment;

FIG. 10 is a view showing a typical sectional structure of a semiconductor storage apparatus according to a second variant of the second embodiment;

FIG. 11 is a view showing a typical sectional structure of a semiconductor storage apparatus according to a third embodiment;

FIG. 12 is a view showing a typical sectional structure showing a semiconductor storage apparatus according to a first variant of the third embodiment;

FIG. 13 is a view showing a typical sectional structure of a semiconductor storage apparatus according to a second variant of the third embodiment;

FIG. 14 is a view showing a typical sectional structure of a semiconductor storage apparatus according to a fourth embodiment;

FIG. 15 is a view showing a typical sectional structure of a semiconductor storage apparatus according to a first variant of the fourth embodiment;

FIG. 16 is a view showing a typical sectional structure of a semiconductor storage apparatus according to a second variant of the fourth embodiment;

FIG. 17 is a diagram showing a circuit structure of a TC unit series connection type FeRAM cell block using a plurality of unit cells of a semiconductor storage apparatus according to one of the first to fourth embodiments;

FIG. 18 is a diagram showing a typical block structure of the TC unit series connection type FeRAM cell array, illustrating an example of a memory cell array using the semiconductor storage apparatus cell according to one of the first to fourth embodiments;

FIG. 19 is a diagram showing a typical block structure of a 1T1C type FeRAM cell array, illustrating an example of the memory cell array using the semiconductor storage apparatus cell according to one of the first to fourth embodiments;

FIG. 20 is a view showing a typical sectional structure of a 1T type semiconductor storage apparatus having an MFIS structure according to a fifth embodiment;

FIG. 21 is a view showing a typical sectional structure of a 1T type semiconductor storage apparatus having an MFMIS structure according to a sixth embodiment;

FIG. 22 is a diagram showing a circuit structure of a 1T type FeRAM using a memory cell of a semiconductor storage apparatus according to one of the fifth and sixth embodiments; and

FIG. 23 is a view showing a typical sectional structure of a memory cell (MRAM) of a semiconductor storage apparatus according to a seventh embodiment.

### DETAILED DESCRIPTION OF THE INVENTION

First to seventh embodiments will be described with reference to the drawings. In the description of the following drawings, the same or similar portions have the same or similar reference numerals. Attention is to be paid to the fact that the drawings are typical and a relationship between a thickness and a planar dimension and a ratio of thicknesses of respective layers are different from actual ones. Accordingly, a specific thickness and dimension is to be decided in consideration of the following description. Moreover, it is a matter of course that portions having different relationships between mutual dimensions and ratios thereof are included in the respective drawings.

Moreover, the first to seventh embodiments which will be described below show an apparatus and method for materializing the technical thought of the invention, and the technical thought of the invention does not specify a material, a shape, a structure and an arrangement of a component to the following ones. The technical thought of the invention can be variously changed within the scope of claims.

### FIRST EMBODIMENT

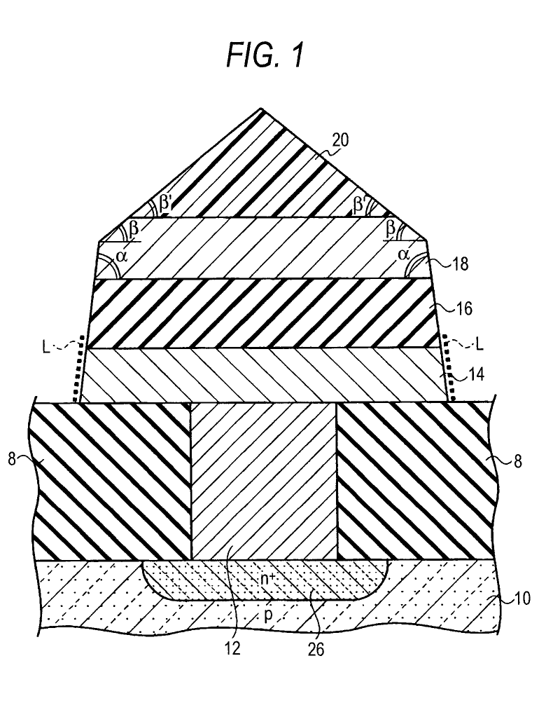

As shown in FIG. 1, a semiconductor storage apparatus according to a first embodiment includes a source-drain diffusion layer 26 of a switching transistor disposed on a semiconductor substrate 10, an interlayer insulating film 8 disposed on the semiconductor substrate 10 and the source-drain diffusion layer 26, a plug electrode 12 embedded in the interlayer insulating film 8 and disposed on the source-drain diffusion layer 26, and a ferroelectric capacitor including a bottom electrode (BE: Bottom Electrode) 14 disposed on the interlayer insulating film 8 and the plug electrode 12, a ferroelectric layer 16 disposed on the bottom electrode 14, and a top electrode (TE: Top Electrode) 18 disposed on the ferroelectric layer (FE: Ferroelectric Layer) 16. A well may be provided on the semiconductor substrate 10, and an element may be formed on the well in some cases.

In the semiconductor storage apparatus according to the first embodiment, an angle α formed by a sidewall portion in a position in which the top electrode 18 is provided in contact with the ferroelectric layer 16 and a surface of the ferroelectric layer 16 is larger than an angle β formed by a sidewall portion on an upper part of the top electrode 18 and the surface of the ferroelectric layer 16.

In the semiconductor storage apparatus according to the first embodiment, the angle β formed by the sidewall portion on the upper part of the top electrode 18 and the surface of the ferroelectric layer 16 is almost equal to an angle β′ formed by a hard mark 20 and a surface of the top electrode 18 as shown in FIG. 1.

In the semiconductor storage apparatus according to the first embodiment, the hard mask 20 has a triangular sectional shape as shown in FIG. 1.

(Manufacturing Method)

A method for manufacturing the semiconductor storage apparatus according to the first embodiment includes a step of forming the source-drain diffusion layer 26 of a switching transistor on the semiconductor substrate 10 and a step of forming the interlayer insulating film 8 on the semiconductor substrate 10 and the source-drain diffusion layer 26. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hardmask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the etching step, a second etching process may be performed after the first etching process is performed. In the second etching process, a chemical etching performance obtained by a chemical reaction is increased more greatly than a physical etching performance.

It is possible to use SrRuO₃ or IrO₂ as the top electrode 18 of the ferroelectric capacitor, for example. It is possible to use PZT (Pb(ZrₓTi₁₋ₓ)O₃) as the ferroelectric layer 16 of the ferroelectric capacitor, for example.

It is possible to use SrRuO₃, Pt, IrO₂, Ir or Ti as the bottom electrode 14 of the ferroelectric capacitor, for example.

As a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}) a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

Description will be given to a relationship between an etching condition in the manufacturing method and a structure of a ferroelectric capacitor.

If the ferroelectric capacitor is processed so that a dropped portion (shoulder drop) over the upper sidewall portion (shoulder portion) of the hard mask 20 is not generated, the sidewall portion of the ferroelectric capacitor becomes substantially vertical and a short circuit (a capacitor leakage) between the top electrode 18 and the bottom electrode 14 may be caused by a residue that is formed on the sidewall portion.

By using the hard mask material that has a lower etching-selectivity than the ferroelectric capacitor material, it is possible to obtain such a shape as to generate a dropped portion (shoulder drop) over the upper sidewall portion (shoulder portion) of the hard mask 20. Also, by enhancing a physical etching effect more greatly than a chemical etching effect, for example, by increasing a bias power of an etching condition and by setting an etching pressure to be equal to or lower than 1.3 Pa, it is possible to obtain such a shape that the shoulder drop is generated on the upper sidewall portion of hard mask 20.

In the first etching process, a physical etching performance is increased more greatly than a chemical etching performance obtained by a chemical reaction. For example, plasma etching or reactive ion etching (RIE), in which a directivity of the ion is enhanced by setting a bias power high and by setting an etching pressure relatively low, can be performed as the first etching process. Also, it is possible to perform a technique such as ion beam etching, ion milling, or bias sputter etching.

Additionally, for example, by prolonging an etching time, the shoulder drops generated on the shoulder portion of the hard mask 20 becomes larger and collides against each other. As a result, the hard mask 20 can have a sharp shape as shown in FIG. 1.

As a gas to be used in the first etching process, a chloric gas (Cl₂, BCl₃), a fluoric gas (CF₄, CHF₃, C₂F₆, C₃F₈) and an inert gas (Ar, Xe, He) are suitable for the ferroelectric layer portion, Pt, titanium aluminum nitride film (TiAl_{X}N_{Y}) and titanium nitride film (Ti_{X}N_{Y}) materials. For Ir, SrRuO₃ or IrO_{X}, moreover, a gas obtained by mixing a chloric gas (Cl₂, BCl₃), a fluoric gas (CF₄, CHF₃, C₂F₆, C₃F₈), an inert gas (Ar, Xe, He), a reduced gas (CO) and N₂ is suitable.

In the second etching process, a chemical etching performance obtained by a chemical reaction is increased more greatly than a physical etching performance. For example, plasma etching or reactive ion etching (RIE), in which a directivity of an ion is reduced by setting a bias power low and by setting an etching pressure relatively high, can be performed as the second etching process. Also, it is possible to perform a technique such as the reactive ion etching using a halogen based gas, or a wet etching technique.

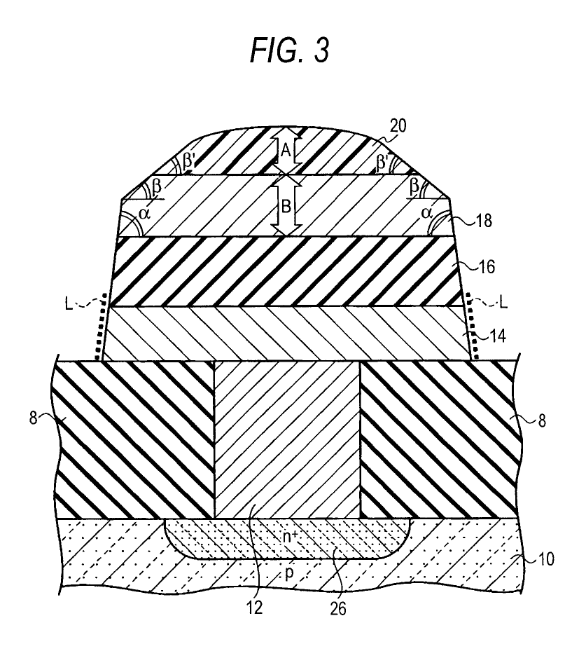

To obtain such a shape that an upper part of the hard mask 20 is rounded as shown in FIG. 3, which will be described below, in addition to a condition in which the physical etching effect is enhanced so that the hard mask 20 has a sharp shape as shown in FIG. 1, a condition in which a chemical etching effect is enhanced may be used as a final etching condition. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 relatively thinner, it is possible to obtain a shape in which a shoulder drop on the top electrode portion is generated as shown in FIGS. 1 and 3.

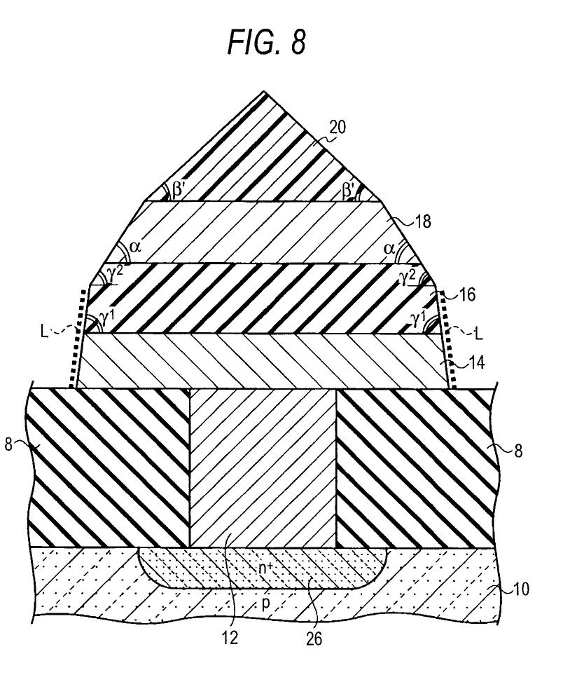

Additionally, by forming the hard mask 20 further thinner than that in the cases of FIGS. 1 and 3, it is possible to obtain such a shape that the shoulder drop is also generated on a part of the ferroelectric layer 16 as shown in FIGS. 8 to 10 which will be described below.

In the semiconductor storage apparatus according to the first embodiment, as shown in FIG. 1, in which the shoulder drop is generated on the top electrode 18 of the ferroelectric capacitor, the top electrode 18 is separated from a leakage portion L that is formed by the residue of the sidewall portion so that a leakage between the top electrode 18 and the bottom electrode 14 is prevented.

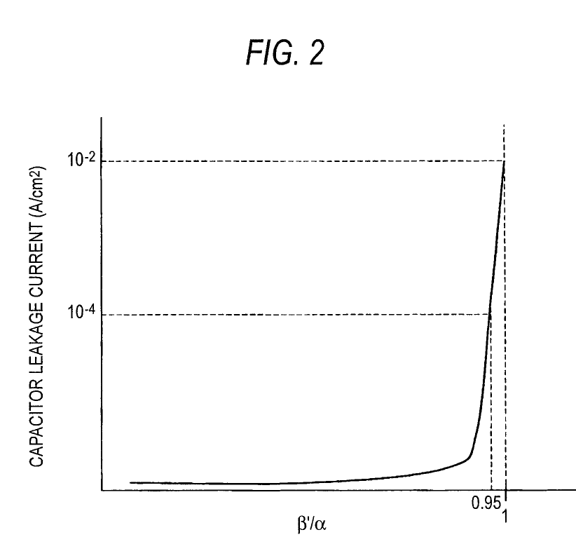

FIG. 2 shows a relationship between an angle ratio of β′/α and a capacitor leakage current in the semiconductor storage apparatus according to the first embodiment. In FIG. 2, a value of the angle α is set to be approximately 74 degrees. In the semiconductor storage apparatus according to the first embodiment, it is apparent that the capacitor leakage current is increased if the angle β formed by the sidewall portion in which the top electrode 18 is provided in contact with the ferroelectric layer 16 and a surface of the ferroelectric layer 16 is equal to the angle β′ formed by the hard mask 20 and the surface of the top electrode 18, and the capacitor leakage current is rapidly decreased when the angle ratio β′/α is equal to or lower than approximately 0.95.

(First Variant)

In a semiconductor storage apparatus according to a first variant of the first embodiment, a shape of a hard mask 20 in a manufacturing process is only different from that in the first embodiment as shown in FIG. 3 and the other components are the same. Therefore, description will be omitted.

In the semiconductor storage apparatus according to the first variant of the first embodiment, as shown in FIG. 3, an angle β formed by a sidewall portion in a position in which a top electrode 18 is provided in contact with a ferroelectric layer 16 and a surface of the ferroelectric layer 16 is larger than an angle β formed by a sidewall portion in an upper part of the top electrode 18 and the surface of the ferroelectric layer 16.

In the semiconductor storage apparatus according to the first variant of the first embodiment, the angle β formed by the sidewall portion in the upper part of the top electrode 18 and the surface of the ferroelectric layer 16 is almost equal to an angle β′ formed by the hard mask 20 and a surface of the top electrode 18 as shown in FIG. 3.

In the semiconductor storage apparatus according to the first variant of the first embodiment, the hard mask 20 has a semicircular sectional shape as shown in FIG. 3.

(Manufacturing Method)

A method for manufacturing the semiconductor storage apparatus according to the first variant of the first embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 3. Moreover, the method includes a step of forming a bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas is performed as a final etching after the first etching process is performed. In the second etching process, a chemical etching performance obtained by a chemical reaction is increased more greatly than a physical etching performance.

In the same manner as in the first embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the first embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), an aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

To obtain such a shape that an upper part of the hard mask 20 is rounded as shown in FIG. 3, in addition to a condition in which the physical etching effect is enhanced so that the hard mask 20 has a sharp shape as shown in FIG. 1, a condition in which a chemical etching effect is enhanced may be used as a final etching condition. As a specific gas for the final etching, a condition that a chloric gas (Cl₂, BCl₃) and a fluoric gas (CF₄, CHF₃, C₂F₆, C₃F₈) are utilized as main gases is suitable.

By forming the hard mask 20 to be relatively thin, it is possible to obtain a shape in which the shoulder drop of the top electrode portion is generated as shown in FIG. 3.

In the semiconductor storage apparatus according to the first variant of the first embodiment, as shown in FIG. 3, the top electrode 18 is separated from a leakage portion L of the sidewall portion of the ferroelectric capacitor so that a leakage is prevented.

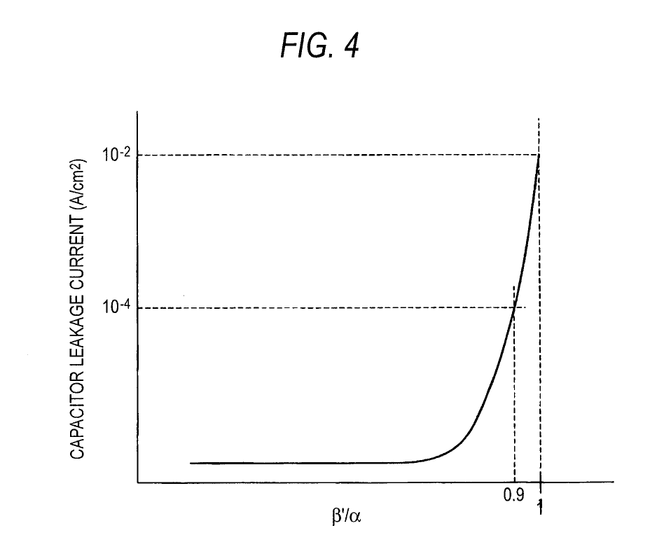

FIG. 4 shows a relationship between an angle ratio of β′/α and a capacitor leakage current in the semiconductor storage apparatus according to the first variant of the first embodiment. In FIG. 4, a value of the angle α is set to be approximately 74 degrees.

In the semiconductor storage apparatus according to the first variant of the first embodiment, it is apparent that the capacitor leakage current is increased if the angle β formed by the sidewall portion in a position in which the top electrode 18 is provided in contact with the ferroelectric layer 16 and a surface of the ferroelectric layer 16 is almost equal to the angle β′ formed by the hard mask 20 and the surface of the top electrode 18, and the capacitor leakage current is rapidly decreased if the angle ratio β′/α is equal to or lower than approximately 0.9.

It is apparent that the capacitor leakage current starts to be decreased when the angle ratio β′/α is decreased, that is, the angle β′ on the hard mask 20 is smaller than the angle α of the top electrode 18. When the angle ratio β′/α is slightly decreased to be approximately 0.9, the capacitor leakage current is reduced by approximately two digits.

A tendency in FIG. 4 becomes remarkable when the angle α formed by the sidewall portion in which the top electrode 18 is provided in contact with the ferroelectric layer 16 and the surface of the ferroelectric layer 16 is equal to or larger than approximately 70 degrees. More specifically, in the ferroelectric capacitor in which the angle α is equal to or larger than approximately 70 degrees, by satisfying a relationship of “the angle β′ of the hard mask 20<the angle α of the top electrode 18”, the capacitor leakage current can be reduced.

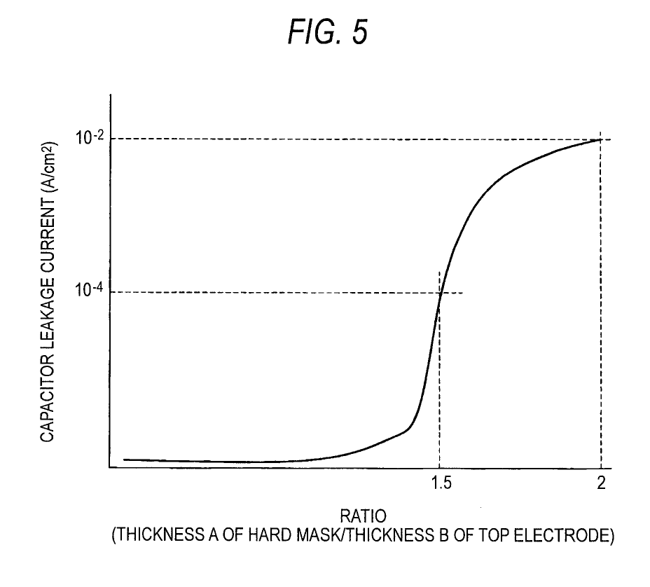

FIG. 5 shows a relationship between the capacitor leakage current and the ratio (a thickness A of the hardmask/a thickness B of the top electrode) in the semiconductor storage apparatus according to the first variant of the first embodiment. In FIG. 5, a value of the angle α is set to be approximately 74 degrees.

Moreover, a value of the thickness B of the top electrode 18 is set to be approximately 100 nm. In the semiconductor storage apparatus according to the first variant of the first embodiment, it is apparent that the capacitor leakage current is rapidly decreased if the ratio (the thickness A of the hard mask/the thickness B of the top electrode) is equal to or lower than approximately 1.5 as shown in FIG. 5.

In the semiconductor storage apparatus according to the first variant of the first embodiment, it is desirable that the thickness of the top electrode 18 should be equal to or smaller than approximately 150 nm in order to control the capacitor leakage current.

(Second Variant)

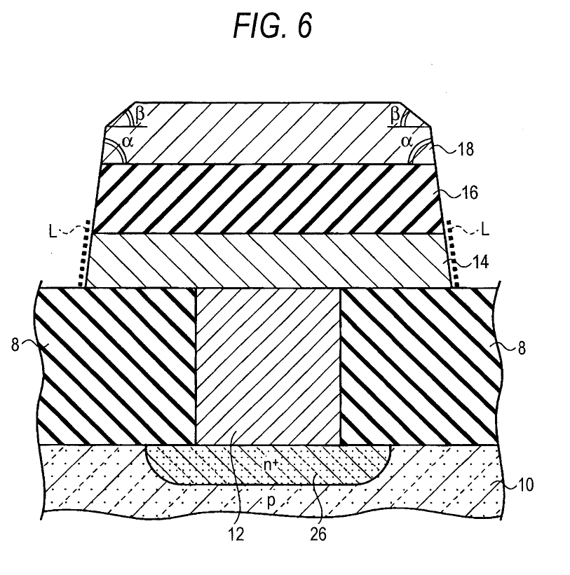

In a semiconductor storage apparatus according to a second variant of the first embodiment, a shape of a hard mask 20 in a manufacturing process is only different from that in the first embodiment as shown in FIG. 6 and the other components are the same. Therefore, description will be omitted. More specifically, in the semiconductor storage apparatus according to the second variant of the first embodiment, most of the hard mask 20 is etched and is not left after a collective processing as shown in FIG. 6.

In the semiconductor storage apparatus according to the second variant of the first embodiment, as shown in FIG. 6, an angle α formed by a sidewall portion in a position in which a top electrode 18 is provided in contact with a ferroelectric layer 16 and a surface of the ferroelectric layer 16 is larger than an angle β formed by a sidewall portion on an upper part of the top electrode 18 and the surface of the ferroelectric layer 16.

(Manufacturing Method)

A method for manufacturing the semiconductor storage apparatus according to the second variant of the first embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 6. Moreover, the method includes a step of forming a bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas may be performed as a final etching after the first etching process is performed. In the second etching process, a chemical etching performance obtained by a chemical reaction is increased more greatly than a physical etching performance.

In the same manner as in the first embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the first embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrOₓ), a titanium oxide film (TiOₓ), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 1, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 3.

By forming the hard mask 20 to be relatively thin, it is possible to obtain a shape in which a shoulder drop of the top electrode portion is generated, and furthermore, the hard mask 20 is completely removed as shown in FIG. 6.

In the semiconductor storage apparatus according to the second variant of the first embodiment, as shown in FIG. 6, the top electrode 18 is separated from a leakage portion L of the sidewall portion of the ferroelectric capacitor so that a leakage is prevented.

(Structure of Ferroelectric Memory Cell Region Portion and Peripheral Region Portion)

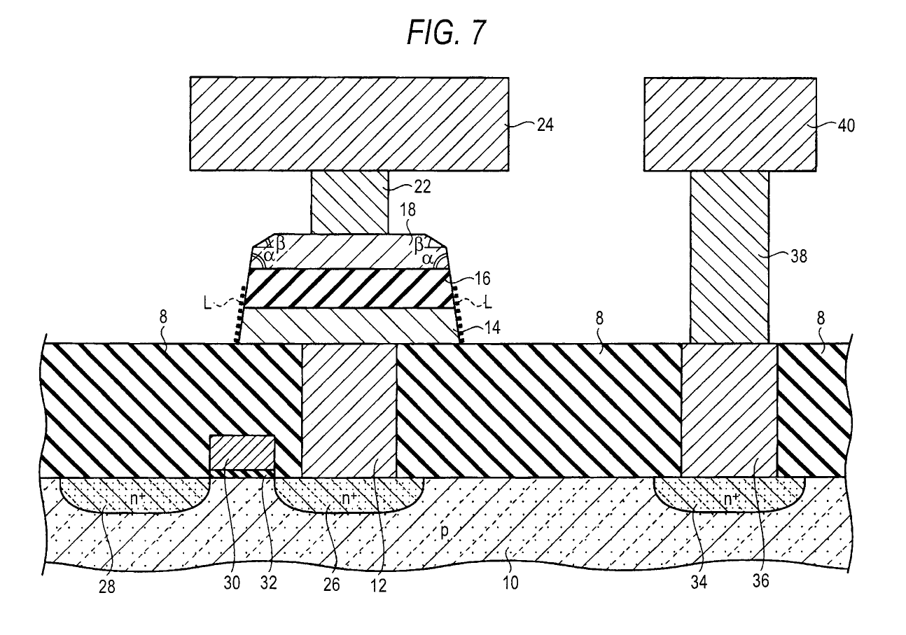

A typical sectional structure including wiring electrodes 24 and 40 of the semiconductor storage apparatus according to the first embodiment is illustrated in a ferroelectric memory cell region portion and a peripheral region portion as shown in FIG. 7.

More specifically, the ferroelectric memory cell region portion includes source-drain diffusion layers 26 and 28 of a switching transistor provided on the semiconductor substrate 10, and a gate insulating film 32 disposed between the source-drain diffusion layers 26 and 28. Furthermore, the ferroelectric memory cell region portion includes a gate electrode 30 provided on the gate insulating film 32, and an interlayer insulating film 8 disposed on the semiconductor substrate 10 and the gate electrode 30. Moreover, the ferroelectric memory cell region portion includes a plug electrode 12 embedded in the interlayer insulating film 8 and disposed on the source-drain diffusion layer 26, and a ferroelectric capacitor including the bottom electrode 14 disposed on the interlayer insulating film 8 and the plug electrode 12, the ferroelectric layer 16 disposed on the bottom electrode 14, and the top electrode 18 disposed on the ferroelectric layer 16. In addition, there are provided a via hole electrode 22 disposed on the top electrode 18 and the wiring electrode 24 disposed on the via hole electrode 22.

Similarly, the peripheral region portion includes a contact diffusion layer 34 provided in the semiconductor substrate 10, and the interlayer insulating film 8 disposed on the semiconductor substrate 10. Furthermore, the peripheral region portion includes a plug electrode 36 embedded in the interlayer insulating film 8 and disposed on the contact diffusion layer 34, a via hole electrode 38 disposed on the interlayer insulating film 8 and the plug electrode 36, and the wiring electrode 40 disposed on the via hole electrode 38.

For a structure of the ferroelectric capacitor shown in FIG. 7, it is possible to apply the semiconductor storage apparatuses shown in the first embodiment, the first variant and the second variant.

According to the semiconductor storage apparatus having a 1-Mask-FeRAM capacitor structure and the method for manufacturing the semiconductor storage apparatus shown in each of the first embodiment, the first variant and the second variant, it is possible to relieve a damage of a sidewall portion and to reduce a capacitor leakage.

### SECOND EMBODIMENT

As shown in FIG. 8, a semiconductor storage apparatus according to a second embodiment includes a source-drain diffusion layer 26 of a switching transistor disposed on a semiconductor substrate 10, and an interlayer insulating film 8 disposed on the semiconductor substrate 10 and the source-drain diffusion layer 26. Moreover, the semiconductor storage apparatus includes a plug electrode 12 embedded in the interlayer insulating film 8 and disposed on the source-drain diffusion layer 26, and a ferroelectric capacitor including a bottom electrode 14 disposed on the interlayer insulating film 8 and the plug electrode 12, a ferroelectric layer 16 disposed on the bottom electrode 14, and a top electrode 18 disposed on the ferroelectric layer 16. A well may be provided on the semiconductor substrate 10, and an element may be formed on the well in some cases.

In the semiconductor storage apparatus according to the second embodiment, an angle γ 1 formed by a sidewall portion in a position in which the ferroelectric layer 16 is provided in contact with the bottom electrode 14 and a surface of the bottom electrode 14 is larger than an angle γ2 formed by the sidewall portion in a position in which the ferroelectric layer 16 is provided in contact with the top electrode 18 and the surface of the bottom electrode 14.

In the semiconductor storage apparatus according to the second embodiment, an angle α formed by the sidewall portion in the position in which the top electrode 18 is provided in contact with the ferroelectric layer 16 and the surface of the ferroelectric layer 16 is larger than an angle β′ formed by a hard mark 20 and a surface of the top electrode 18.

In the semiconductor storage apparatus according to the second embodiment, the hard mask 20 has a triangular sectional shape as shown in FIG. 8.

(Manufacturing Method)

A method for manufacturing the semiconductor storage apparatus according to the second embodiment includes a step of forming the source-drain diffusion layer 26 of a switching transistor on the semiconductor substrate 10 and a step of forming the interlayer insulating film 8 on the semiconductor substrate 10 and the source-drain diffusion layer 26. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hardmask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

It is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

As a hardmask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

Description will be given to a relationship between an etching condition in the manufacturing method and a structure of a ferroelectric capacitor.

In the case in which the hard mask material has a lower etching-selectivity than the ferroelectric capacitor material, it is possible to obtain such a shape as to generate a dropped portion (shoulder drop) over the upper sidewall portion (shoulder portion) of the hard mask 20. Also, by enhancing a physical etching effect more greatly than a chemical etching effect, for example, by increasing a bias power of an etching condition and by setting an etching pressure to be equal to or lower than 1.3 Pa, it is possible to obtain such a shape that the shoulder drop is generated on the upper sidewall portion of hard mask 20.

Additionally, for example, by prolonging an etching time, the shoulder drops generated on the shoulder portion of the hard mask 20 becomes larger and collides against each other. As a result, the hard mask 20 can have a sharp shape as shown in FIG. 8.

As an etching gas to be used on the etching condition, a chloric gas (Cl₂, BCl₃), a fluoric gas (CF₄, CHF₃, C₂F₆, C₃F₈) and an inert gas (Ar, Xe, He) are suitable for the ferroelectric layer portion, Pt, titanium aluminum nitride film (TiAl_{X}N_{Y}) and titanium nitride film (Ti_{X}N_{Y}) materials. A gas obtained by mixing a chloric gas (Cl₂, BCl₃), a fluoric gas (CF₄, CHF₃, C₂F₆, C₃F₈), an inert gas (Ar, Xe, He), a reduced gas (CO) and N₂) is suitable for Ir, SrRuO₃ or IrO_{X}.

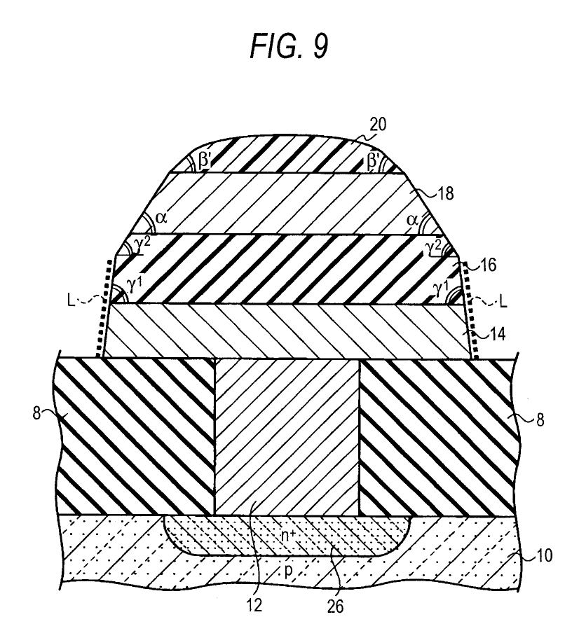

As shown in FIG. 8, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 9 which will be described below. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 to be relatively thin, it is possible to obtain a shape in which the shoulder drop of the top electrode portion is generated, and furthermore, the shoulder drop is generated on a part of the ferroelectric layer 16 as shown in FIG. 8.

In the semiconductor storage apparatus according to the second embodiment, as shown in FIG. 8, the top electrode 18 is separated from a leakage portion L of the sidewall portion of the ferroelectric capacitor so that a leakage is prevented. By forming the ferroelectric layer 16 to have a two-step shape, particularly, the top electrode 18 is further separated from the leakage portion L of the sidewall portion of the ferroelectric capacitor as compared with that in the first embodiment. Thus, a leakage is prevented.

(First Variant)

In a semiconductor storage apparatus according to a first variant of the second embodiment, a shape of a hard mask 20 in a manufacturing process is only different from that in the second embodiment as shown in FIG. 9 and the other components are the same. Therefore, description will be omitted.

In the semiconductor storage apparatus according to the first variant of the second embodiment, an angle γ1 formed by a sidewall portion in a position in which a ferroelectric layer 16 is provided in contact with a bottom electrode 14 and a surface of the bottom electrode 14 is larger than an angle γ2 formed by a sidewall portion in a position in which the ferroelectric layer 16 is provided in contact with a top electrode 18 and the surface of the bottom electrode 14.

In the semiconductor storage apparatus according to the first variant of the second embodiment, an angle α formed by a sidewall portion in a position in which the top electrode 18 is provided in contact with the ferroelectric layer 16 and a surface of the ferroelectric layer 16 is larger than an angle β′ formed by the hardmask 20 and a surface of the top electrode 18.

In the semiconductor storage apparatus according to the first variant of the second embodiment, the hard mask 20 has a semicircular sectional shape as shown in FIG. 9.

(Manufacturing Method)

A method for manufacturing the semiconductor storage apparatus according to the first variant of the second embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 9. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas is performed as a final etching after the first etching process is performed. In the second etching process, a chemical etching performance obtained by a chemical reaction is increased more greatly than a physical etching performance.

In the same manner as in the second embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the second embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 8, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 9. A specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 to be relatively thin, it is possible to obtain such a shape that a shoulder drop of the top electrode portion is generated, and furthermore, the shoulder drop is generated on a part of the ferroelectric layer 16 as shown in FIG. 9.

In the semiconductor storage apparatus according to the first variant of the second embodiment, as shown in FIG. 9, the top electrode 18 is separated from a leakage portion L of the sidewall portion of the ferroelectric capacitor so that a leakage is prevented.

In particular, the ferroelectric layer 16 is formed to have a two-step shape so that the top electrode 18 is further separated from the leakage portion L of the sidewall portion of the ferroelectric capacitor as compared with that in the first embodiment. Thus, a leakage is prevented.

(Second Variant)

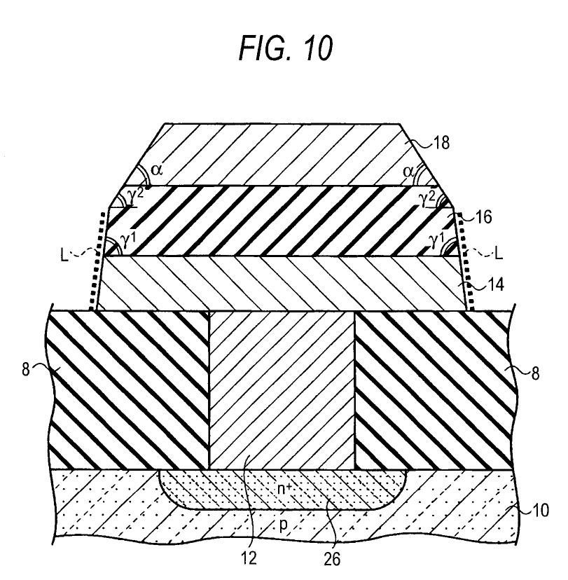

In a semiconductor storage apparatus according to a second variant of the second embodiment, a shape of a hard mask 20 in a manufacturing process is only different from that in the second embodiment as shown in FIG. 10 and the other components are the same. Therefore, description will be omitted. More specifically, in the semiconductor storage apparatus according to the second variant of the second embodiment, most of the hard mask 20 is etched and is not left after a collective processing as shown in FIG. 10.

In the semiconductor storage apparatus according to the second variant of the second embodiment, an angle γ1 formed by a sidewall portion in a position in which a ferroelectric layer 16 is provided in contact with a bottom electrode 14 and a surface of the bottom electrode 14 is larger than an angle γ2 formed by a sidewall portion in a position in which the ferroelectric layer 16 is provided in contact with a top electrode 18 and the surface of the bottom electrode 14.

(Manufacturing Method)

A method for manufacturing the semiconductor storage apparatus according to the second variant of the second embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 10. Moreover, the method includes a step of forming the bottom electrode 14 on the interlayer insulating film 8, a step of forming the ferroelectric layer 16 on the bottom electrode 14, a step of forming the top electrode 18 on the ferroelectric layer 16, a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas may be performed as a final etching after the first etching process is performed. In the second etching process, a chemical etching performance obtained by a chemical reaction is increased more greatly than a physical etching performance.

In the same manner as in the second embodiment, it is possible to use SrRuO₃ or IrO₂ for the top electrode 18 of a ferroelectric capacitor, for example. It is possible to use PZT (Pb(Zr_{X}Ti₁₋ₓ)O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the second embodiment, as a hard mask material to be formed on the ferroelectric capacitor, for example, it is possible to use a single layer of an oxide film (SiO₂), a titanium nitride film (TixNy), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 8, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 9.

By forming the hard mask 20 to be relatively thin, furthermore, it is possible to obtain a shape in which a shoulder drop of the top electrode portion is generated, and furthermore, the hard mask 20 is completely removed as shown in FIG. 10.

As shown in FIG. 10, moreover, it is possible to obtain such a shape that the shoulder drop is generated on a part of the ferroelectric layer 16.

In the semiconductor storage apparatus according to the second variant of the second embodiment, as shown in FIG. 10, the top electrode 18 is separated from a leakage portion L of the sidewall portion of the ferroelectric capacitor so that a leakage is prevented.

In particular, the ferroelectric layer 16 is formed to have a two-step shape so that the top electrode 18 is further separated from the leakage portion L of the sidewall portion of the ferroelectric capacitor as compared with that in the first embodiment. Thus, a leakage is prevented.

According to the semiconductor storage apparatus having a 1-Mask-FeRAM capacitor structure and the method for manufacturing the semiconductor storage apparatus shown in each of the second embodiment, the first variant and the second variant, it is possible to relieve a damage of a sidewall portion and to reduce a capacitor leakage.

### THIRD EMBODIMENT

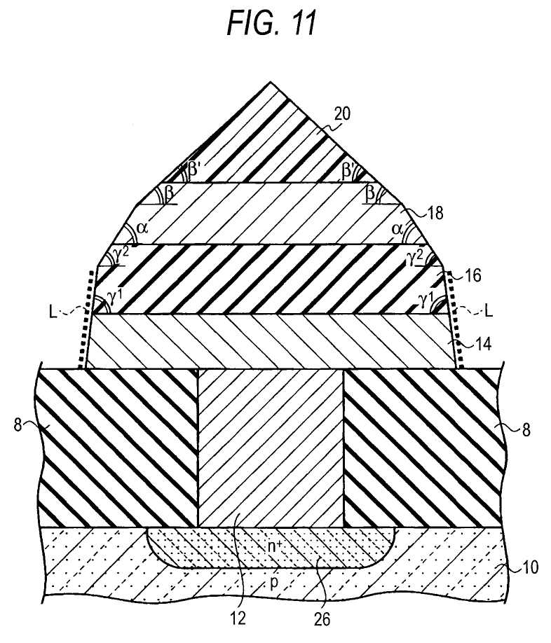

As shown in FIG. 11, a semiconductor storage apparatus according to a third embodiment includes a source-drain diffusion layer 26 of a switching transistor disposed on a semiconductor substrate 10, and an interlayer insulating film 8 disposed on the semiconductor substrate 10 and the source-drain diffusion layer 26. Moreover, the semiconductor storage apparatus includes a plug electrode 12 embedded in the interlayer insulating film 8 and disposed on the source-drain diffusion layer 26, and a ferroelectric capacitor including a bottom electrode 14 disposed on the interlayer insulating film 8 and the plug electrode 12, a ferroelectric layer 16 disposed on the bottom electrode 14, and a top electrode 18 disposed on the ferroelectric layer 16. A well may be provided on the semiconductor substrate 10, and an element may be formed on the well in some cases.

In the semiconductor storage apparatus according to the third embodiment, an angle γ1 formed by a sidewall portion in a position in which the ferroelectric layer 16 is provided in contact with the bottom electrode 14 and a surface of the bottom electrode 14 is larger than an angle γ2 formed by the sidewall portion in a position in which the ferroelectric layer 16 is provided in contact with the top electrode 18 and the surface of the bottom electrode 14.

In the semiconductor storage apparatus according to the third embodiment, furthermore, an angle α formed by a sidewall portion in a position in which the top electrode 18 is provided in contact with the ferroelectric layer 16 and a surface of the ferroelectric layer 16 is larger than an angle β formed by a sidewall portion in an upper part of the top electrode 18 and the surface of the ferroelectric layer 16.

In the semiconductor storage apparatus according to the third embodiment, the angle α formed by the sidewall portion in the position in which the top electrode 18 is provided in contact with the ferroelectric layer 16 and the surface of the ferroelectric layer 16 is larger than an angle β′ formed by a hard mask 20 and a surface of the top electrode 18.

In the semiconductor storage apparatus according to the third embodiment, the hard mask 20 has a triangular sectional shape as shown in FIG. 11.

(Manufacturing Method)

A method for manufacturing the semiconductor storage apparatus according to the third embodiment includes a step of forming the source-drain diffusion layer 26 of a switching transistor on the semiconductor substrate 10 and a step of forming the interlayer insulating film 8 on the semiconductor substrate 10 and the source-drain diffusion layer 26. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hardmask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

It is possible to use SrRuO₃ or IrO₂ as the top electrode 18 of the ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

As a hardmask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

Description will be given to a relationship between an etching condition in the manufacturing method and a structure of the ferroelectric capacitor.

In the case in which the hard mask material has a lower etching-selectivity than the ferroelectric capacitor material, it is possible to obtain such a shape as to generate a dropped portion (shoulder drop) over the upper sidewall portion (shoulder portion) of the hard mask 20. Also, by enhancing a physical etching effect more greatly than a chemical etching effect, for example, by increasing a bias power of an etching condition and by setting an etching pressure to be equal to or lower than 1.3 Pa, it is possible to obtain such a shape that the shoulder drop is generated on the upper sidewall portion of hard mask 20.

Additionally, for example, by prolonging an etching time, the shoulder drops generated on the shoulder portion of the hard mask 20 becomes larger and collides against each other. As a result, the hard mask 20 can have a sharp shape as shown in FIG. 11.

As an etching gas to be used in the etching condition, a chloric gas (Cl₂, BCl₃), a fluoric gas (CF₄, CHF₃, C₂F₆, C₃F₈) and an inert gas (Ar, Xe, He) are suitable for the ferroelectric layer portion, Pt, titanium aluminum nitride film (TiAl_{X}N_{Y}) and titanium nitride film (Ti_{X}N_{Y}) materials. For Ir, SrRuO₃ or IrO_{X}, a gas obtained by mixing a chloric gas (Cl₂, BCl₃), a fluoric gas (CF₄, CHF₃, C₂F₆, C₃F₈), an inert gas (Ar, Xe, He), a reduced gas (CO) and N₂ is suitable.

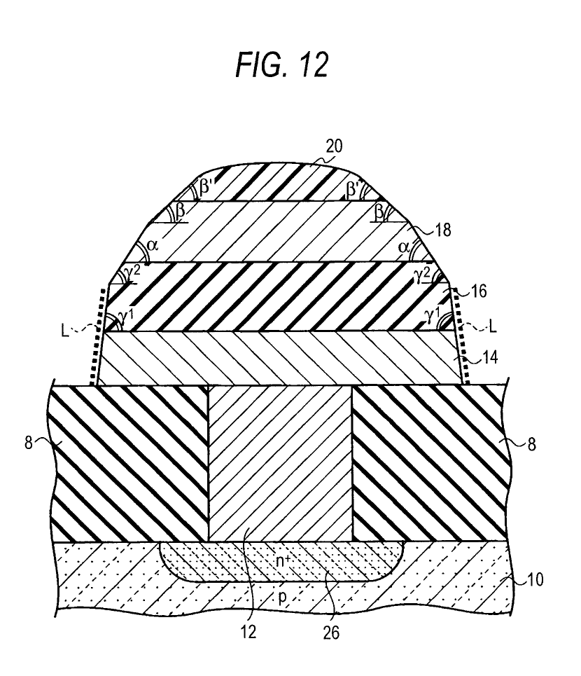

As shown in FIG. 11, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 12 which will be described below. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 to be relatively thin, furthermore, it is possible to obtain a shape in which the shoulder drop of the top electrode portion is generated, and furthermore, the shoulder drop is generated on a part of the ferroelectric layer 16 as shown in FIG. 11.

In the semiconductor storage apparatus according to the third embodiment, the top electrode 18 is separated from a leakage portion L of the sidewall portion of the ferroelectric capacitor as shown in FIG. 11. Thus, a leakage is prevented.

In particular, the ferroelectric layer 16 is formed to have a two-step shape so that the top electrode 18 is further separated from the leakage portion L of the sidewall portion of the ferroelectric capacitor as compared with that in the first embodiment. Thus, a leakage is prevented.

In addition, a relationship between a capacitor leakage current and an angle ratio β′/α in the semiconductor storage apparatus according to the third embodiment can be represented in the same manner as in FIG. 2.

In the semiconductor storage apparatus according to the third embodiment, the capacitor leakage current is increased if the angle α formed by the sidewall portion in which the top electrode 18 is provided in contact with the ferroelectric layer 16 and a surface of the ferroelectric layer 16 is equal to the angle β′ formed by the hard mask 20 and the surface of the top electrode 18, and the capacitor leakage current is rapidly decreased if the angle ratio β′/α is equal to or lower than approximately 0.95.

(First Variant)

In a semiconductor storage apparatus according to a first variant of the third embodiment, a shape of a hard mask 20 is only different from that in the third embodiment as shown in FIG. 12 and the other components are the same. Therefore, description will be omitted.

In the semiconductor storage apparatus according the first variant of the third embodiment, an angle γ 1 formed by a sidewall portion in a position in which a ferroelectric layer 16 is provided in contact with a bottom electrode 14 and a surface of the bottom electrode 14 is larger than an angle γ 2 formed by a sidewall portion in a position in which the ferroelectric layer 16 is provided in contact with a top electrode 18 and the surface of the bottom electrode 14.

In the semiconductor storage apparatus according to the first variant of the third embodiment, furthermore, an angle α formed by a sidewall portion in a position in which the top electrode 18 is provided in contact with the ferroelectric layer 16 and a surface of the ferroelectric layer 16 is larger than an angle β formed by a sidewall portion in an upper part of the top electrode 18 and the surface of the ferroelectric layer 16.

In the semiconductor storage apparatus according to the first variant of the third embodiment, the angle γ1 formed by the sidewall portion in the position in which the top electrode 18 is provided in contact with the ferroelectric layer 16 and the surface of the ferroelectric layer 16 is larger than an angle β′ formed by the hard mask 20 and a surface of the top electrode 18.

In the semiconductor storage apparatus according to the first variant of the third embodiment, the hard mask 20 has a semicircular sectional shape as shown in FIG. 12.

(Manufacturing Method)

A method for manufacturing the semiconductor storage apparatus according to the first variant of the third embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 12. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas is performed as a final etching after the first etching process is performed. In the second etching process, a chemical etching performance obtained by a chemical reaction is increased more greatly than a physical etching performance.

In the same manner as in the third embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the third embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 11, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 12. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 to be relatively thin, it is possible to obtain a shape in which a shoulder drop of the top electrode portion is generated, and furthermore, the shoulder drop is generated on a part of the ferroelectric layer 16 as shown in FIG. 12.

In the semiconductor storage apparatus according to the first variant of the third embodiment, the top electrode 18 is separated from a leakage portion L of the sidewall portion of the ferroelectric capacitor as shown in FIG. 12. Thus, a leakage is prevented.

In particular, the ferroelectric layer 16 is formed to have a two-step shape so that the top electrode 18 is further separated from the leakage portion L of the sidewall portion of the ferroelectric capacitor as compared with that in the first embodiment. Thus, a leakage is prevented.

In addition, a relationship between a capacitor leakage current and an angle ratio β′/α in the semiconductor storage apparatus according to the first variant of the third embodiment can be represented in the same manner as in FIG. 4.

In the semiconductor storage apparatus according to the first variant of the third embodiment, the capacitor leakage current is increased if the angle α formed by the sidewall portion in the position in which the top electrode 18 is provided in contact with the ferroelectric layer 16 and a surface of the ferroelectric layer 16 is equal to the angle β′ formed by the hard mask 20 and the surface of the top electrode 18.

The capacitor leakage current is rapidly decreased if the angle ratio β′/α is equal to or lower than approximately 0.9.

The capacitor leakage current starts to be decreased when the angle ratio β′/α is decreased, that is, the angle β′ of the hard mask 20 is smaller than the angle α of the top electrode 18.

When the angle ratio β′/α is slightly decreased to be approximately 0.9, the capacitor leakage current is reduced by approximately two digits. The tendency becomes remarkable when the angle α formed by the sidewall portion in which the top electrode 18 is provided in contact with the ferroelectric layer 16 and the surface of the ferroelectric layer 16 is equal to or larger than approximately 70 degrees.

More specifically, in the ferroelectric capacitor in which the angle α is equal to or larger than approximately 70 degrees, by satisfying a relationship of “the angle β′ of the hard mask 20<the angle α of the top electrode 18”, the capacitor leakage current can be reduced.

A relationship between the capacitor leakage current and the ratio (a thickness A of the hard mask/a thickness B of the top electrode) in the semiconductor storage apparatus according to the first variant of the third embodiment can be represented in the same manner as in FIG. 5.

In the semiconductor storage apparatus according to the first variant of the third embodiment, the capacitor leakage current is rapidly decreased if the ratio (the thickness A of the hard mask/the thickness B of the top electrode) is equal to or lower than 1.5.

In the semiconductor storage apparatus according to the first variant of the third embodiment, it is desirable that the thickness of the top electrode 18 should be equal to or smaller than approximately 150 nm in order to control the capacitor leakage current.

(Second Variant)

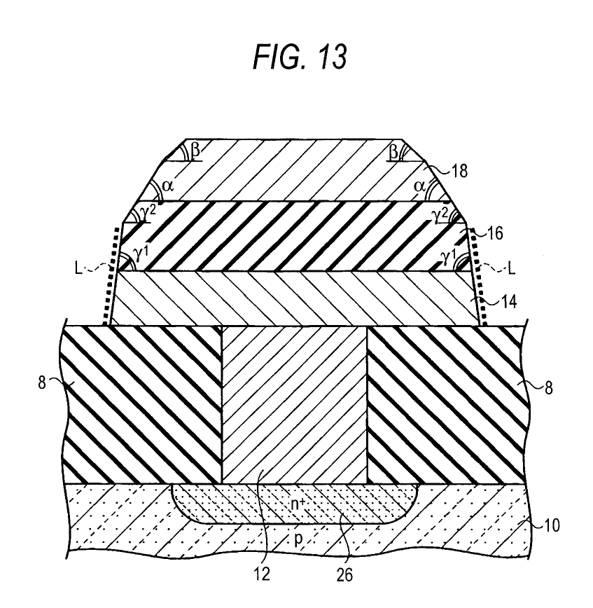

In a semiconductor storage apparatus according to a second variant of the third embodiment, a shape of a hard mask 20 in a manufacturing process is only different from that in the third embodiment as shown in FIG. 13 and the other components are the same. Therefore, description will be omitted. More specifically, in the semiconductor storage apparatus according to the second variant of the third embodiment, most of the hard mask 20 is etched and is not left after a collective processing as shown in FIG. 13.

In the method for manufacturing the semiconductor storage apparatus according to the second variant of the third embodiment, most of the hard mask 20 is etched and is not left after the collective processing as shown in FIG. 13.

In the semiconductor storage apparatus according to the second variant of the third embodiment, an angle γ1 formed by a sidewall portion in a position in which a ferroelectric layer 16 is provided in contact with a bottom electrode 14 and a surface of the bottom electrode 14 is larger than an angle γ2 formed by a sidewall portion in a position in which the ferroelectric layer 16 is provided in contact with a top electrode 18 and the surface of the bottom electrode 14.

In the semiconductor storage apparatus according to the second variant of the third embodiment, moreover, an angle α formed by the sidewall portion in the position in which the top electrode 18 is provided in contact with the ferroelectric layer 16 and the surface of the ferroelectric layer 16 is larger than an angle β formed by a sidewall portion of an upper part of the top electrode 18 and the surface of the ferroelectric layer 16.

(Manufacturing Method)

A method for manufacturing the semiconductor storage apparatus according to the second variant of the third embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 13. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas may be performed as a final etching after the first etching process is performed. In the second etching process, a chemical etching performance obtained by a chemical reaction is increased more greatly than a physical etching performance.

In the same manner as in the third embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the third embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 11, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 12.

By forming the hard mask 20 to be relatively thin, furthermore, it is possible to obtain a shape in which a shoulder drop of the top electrode portion is generated, and furthermore, the hard mask 20 is completely removed as shown in FIG. 13. As shown in FIG. 13, moreover, it is possible to obtain such a shape that the shoulder drop is generated on a part of the ferroelectric layer 16.

In the semiconductor storage apparatus according to the second variant of the third embodiment, as shown in FIG. 13, the top electrode 18 is separated from a leakage portion L of the sidewall portion of the ferroelectric capacitor so that a leakage is prevented.

In particular, the ferroelectric layer 16 is formed to have a two-step shape so that the top electrode 18 is further separated from the leakage portion L of the sidewall portion of the ferroelectric capacitor as compared with that in the first embodiment. Thus, a leakage is prevented.

According to the semiconductor storage apparatus having a 1-Mask-FeRAM capacitor structure and the method for manufacturing the semiconductor storage apparatus shown in each of the third embodiment, the first variant and the second variant, it is possible to relieve a damage of a sidewall portion and to reduce a capacitor leakage.

### FOURTH EMBODIMENT

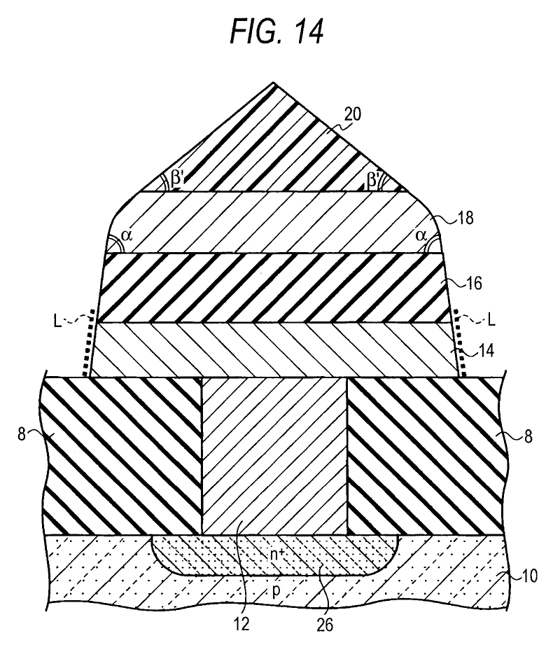

As shown in FIG. 14, a semiconductor storage apparatus according to a fourth embodiment includes a source-drain diffusion layer 26 of a switching transistor disposed on a semiconductor substrate 10, and an interlayer insulating film 8 disposed on the semiconductor substrate 10 and the source-drain diffusion layer 26. Moreover, the semiconductor storage apparatus includes a plug electrode 12 embedded in the interlayer insulating film 8 and disposed on the source-drain diffusion layer 26, and a ferroelectric capacitor including a bottom electrode 14 disposed on the interlayer insulating film 8 and the plug electrode 12, a ferroelectric layer 16 disposed on the bottom electrode 14, and a top electrode 18 disposed on the ferroelectric layer 16. A well may be provided on the semiconductor substrate 10, and an element may be formed on the well in some cases.

In the semiconductor storage apparatus according to the fourth embodiment, as shown in FIG. 14, the sidewall portion of the upper part of the top electrode 18 has a roundness and an angle α formed by a sidewall portion in a position in which the top electrode 18 is provided in contact with the ferroelectric layer 16 and a surface of the ferroelectric layer 16 is larger than an angle formed by a sidewall portion in an upper part of the top electrode 18 and the surface of the ferroelectric layer 16.

In the semiconductor storage apparatus according to the fourth embodiment, the sidewall portion of the upper part of the top electrode 18 has a roundness, and the angle formed by the sidewall portion in the upper part of the top electrode 18 and the surface of the ferroelectric layer 16 is almost equal to an angle β′ formed by a hard mask 20 and a surface of the top electrode 18 as shown in FIG. 14.

In the semiconductor storage apparatus according to the fourth embodiment, the hard mask 20 has a triangular sectional shape as shown in FIG. 14.

(Manufacturing Method)

A method for manufacturing the semiconductor storage apparatus according to the fourth embodiment includes a step of forming the source-drain diffusion layer 26 of a switching transistor on the semiconductor substrate 10 and a step of forming the interlayer insulating film 8 on the semiconductor substrate 10 and the source-drain diffusion layer 26. Moreover, the method includes a step of forming the bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hardmask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

It is possible to use SrRuO₃ or IrO₂ as the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

As a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

Description will be given to a relationship between an etching condition in the manufacturing method and a structure of a ferroelectric capacitor.

In the case in which the hard mask material has a lower etching-selectivity than the ferroelectric capacitor material, it is possible to obtain such a shape as to generate a dropped portion (shoulder drop) over the upper sidewall portion (shoulder portion) of the hard mask 20. Also, by enhancing a physical etching effect more greatly than a chemical etching effect, for example, by increasing a bias power of an etching condition and by setting an etching pressure to be equal to or lower than 1.3 Pa, it is possible to obtain such a shape that the shoulder drop is generated on the upper sidewall portion of hard mask 20.

Additionally, for example, by prolonging an etching time, the shoulder drops generated on the shoulder portion of the hard mask 20 becomes larger and collides against each other. As a result, the hard mask 20 can have a sharp shape as shown in FIG. 14.

As an etching gas to be used in the etching condition, a chloric gas (Cl₂, BCl₃), a fluoric gas (CF₄, CHF₃, C₂F₆, C₃F₈) and an inert gas (Ar, Xe, He) are suitable for the ferroelectric layer portion, Pt, titanium aluminum nitride film (TiAl_{X}N_{Y}) and titanium nitride film (Ti_{X}N_{Y}) materials. For Ir, SrRuO₃ or IrO_{X}, moreover, a gas obtained by mixing a chloric gas (Cl₂, BCl₃), a fluoric gas (CF₄, CHF₃, C₂F₆, C₃F₈), an inert gas (Ar, Xe, He), a reduced gas (CO) and N₂ is suitable.

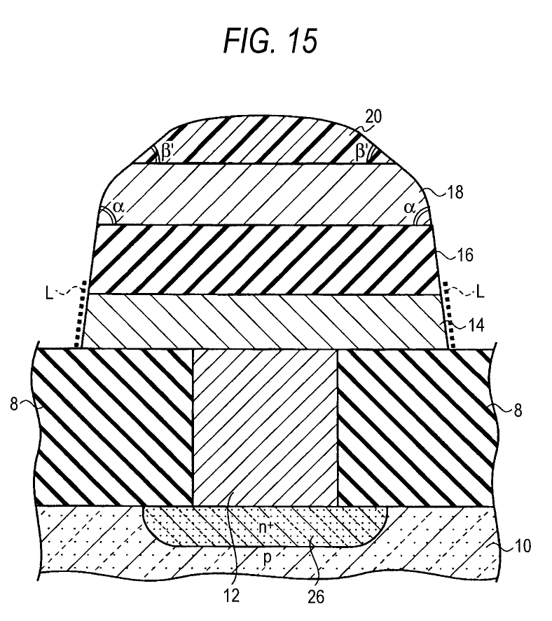

As shown in FIG. 14, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 15 which will be described below. As a specific gas for the final etching, a condition that a chloric gas (Cl₂, BCl₃) and a fluoric gas (CF₄, CHF₃, C₂F₆, C₃F₈) are utilized for main gases is suitable.

In the description, thicknesses of the hard mask 20 in FIGS. 14 and 15 correspond to the case in which it has such a sufficient thickness as to process the ferroelectric capacitor material.

By forming the hard mask 20 to be relatively thin, it is possible to obtain a shape in which the shoulder drop of the top electrode portion is generated.

As shown in FIG. 14, furthermore, it is possible to obtain the sidewall portion of the upper part of the top electrode 18 which has a round shape by reducing a bias of the etching condition and utilizing a chemical etching effect.

In the semiconductor storage apparatus according to the fourth embodiment, as shown in FIG. 14, the sidewall portion in the vicinity of the surface of the top electrode 18 is caused to have the roundness, and the top electrode 18 is separated from a leakage portion L of the sidewall portion of the ferroelectric capacitor so that a leakage is prevented.

A relationship between the capacitor leakage current and an angle ratio β′/α in the semiconductor storage apparatus according to the fourth embodiment can be represented in the same manner as in FIG. 2.

In the semiconductor storage apparatus according to the fourth embodiment, the capacitor leakage current is increased if the angle α formed by the sidewall portion in which the top electrode 18 is provided in contact with the ferroelectric layer 16 and a surface of the ferroelectric layer 16 is equal to the angle β′ formed by the hard mask 20 and the surface of the top electrode 18, and the capacitor leakage current is rapidly decreased if the angle ratio β′/α is equal to or lower than approximately 0.95.

(First Variant)

In a semiconductor storage apparatus according to a first variant of the fourth embodiment, a shape of a hard mask 20 in a manufacturing process is only different from that in the fourth embodiment as shown in FIG. 15 and the other components are the same. Therefore, description will be omitted.

In the semiconductor storage apparatus according to the first variant of the fourth embodiment, as shown in FIG. 15, a sidewall portion of an upper part of a top electrode 18 has a roundness and an angle α formed by a sidewall portion in a position in which the top electrode 18 is provided in contact with a ferroelectric layer 16 and a surface of the ferroelectric layer 16 is larger than an angle formed by the sidewall portion in the upper part of the top electrode 18 and the surface of the ferroelectric layer 16.

In the semiconductor storage apparatus according to the first variant of the fourth embodiment, the sidewall portion of the upper part of the top electrode 18 has a roundness, and the angle formed by the sidewall portion in the upper part of the top electrode 18 and the surface of the ferroelectric layer 16 is almost equal to an angle β′ formed by the hard mask 20 and a surface of the top electrode 18 as shown in FIG. 15.

In the semiconductor storage apparatus according to the first variant of the fourth embodiment, the hard mask 20 has a semicircular sectional shape as shown in FIG. 15.

(Manufacturing Method)

A method for manufacturing the semiconductor storage apparatus according to the first variant of the fourth embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 15. Moreover, the method includes a step of forming a bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas is performed as a final etching after the first etching process is performed. In the second etching process, a chemical etching performance obtained by a chemical reaction is increased more greatly than a physical etching performance.

In the same manner as in the fourth embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the fourth embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), an aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 14, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 15. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 20 to be relatively thin, it is possible to obtain a shape in which a shoulder drop of the top electrode portion is generated.

As shown in FIG. 15, furthermore, it is possible to obtain the sidewall portion of the upper part of the top electrode 18 which has a round shape by reducing a bias of the etching condition and utilizing a chemical etching effect.

In the semiconductor storage apparatus according to the first variant of the fourth embodiment, as shown in FIG. 15, the sidewall portion of the upper part of the top electrode 18 is caused to have the roundness, and the top electrode 18 is separated from a leakage portion L of the sidewall portion of the ferroelectric capacitor so that a leakage is prevented.

A relationship between the capacitor leakage current and an angle ratio β′/α in the semiconductor storage apparatus according to the first variant of the fourth embodiment can be represented in the same manner as in FIG. 4.

In the semiconductor storage apparatus according to the first variant of the fourth embodiment, the capacitor leakage current is increased if the angle α formed by the sidewall portion in which the top electrode 18 is provided in contact with the ferroelectric layer 16 and a surface of the ferroelectric layer 16 is equal to the angle β′ formed by the hard mask 20 and the surface of the top electrode 18, and the capacitor leakage current is rapidly decreased if the angle ratio β′/α is equal to or lower than approximately 0.9.

The capacitor leakage current starts to be decreased when the angle ratio β′/α is decreased, that is, the angle β′ of the hard mask 20 is smaller than the angle α of the top electrode 18.

When the angle ratio β′/α is slightly decreased to be approximately 0.9, the capacitor leakage current is reduced by approximately two digits. The tendency becomes remarkable when the angle α formed by the sidewall portion in a position in which the top electrode 18 is provided in contact with the ferroelectric layer 16 and the surface of the ferroelectric layer 16 is equal to or larger than approximately 70 degrees.

More specifically, in the ferroelectric capacitor in which the angle α is equal to or larger than approximately 70 degrees, by satisfying a relationship of “the angle β′ of the hard mask 20<the angle α of the top electrode 18”, the capacitor leakage current can be reduced.

A relationship between the capacitor leakage current and the ratio (a thickness A of the hard mask/a thickness B of the top electrode) in the semiconductor storage apparatus according to the first variant of the fourth embodiment can be represented in the same manner as in FIG. 5.

In the semiconductor storage apparatus according to the first variant of the fourth embodiment, the capacitor leakage current is rapidly decreased if the ratio (the thickness A of the hard mask 20/the thickness B of the top electrode 18) is equal to or lower than approximately 1.5.

In the semiconductor storage apparatus according to the first variant of the fourth embodiment, it is desirable that the thickness of the top electrode 18 should be equal to or smaller than approximately 150 nm in order to control the capacitor leakage current.

(Second Variant)

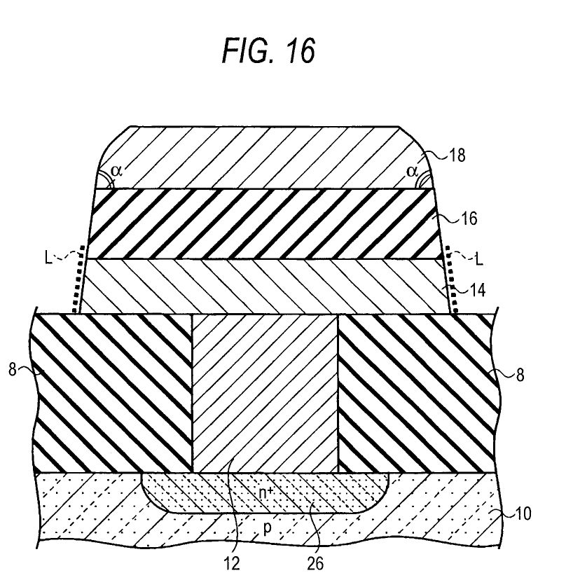

In a semiconductor storage apparatus according to a second variant of the fourth embodiment, a shape of a hard mask 20 in a manufacturing process is only different from that in the fourth embodiment as shown in FIG. 16 and the other components are the same. Therefore, description will be omitted. More specifically, in the semiconductor storage apparatus according to the second variant of the fourth embodiment, most of the hard mask 20 is etched and is not left after a collective processing as shown in FIG. 16.

In the semiconductor storage apparatus according to the second variant of the fourth embodiment, as shown in FIG. 16, a sidewall portion of an upper part of a top electrode 18 has a roundness and an angle α formed by a sidewall portion in a position in which the top electrode 18 is provided in contact with a ferroelectric layer 16 and a surface of the ferroelectric layer 16 is larger than an angle formed by a sidewall portion in an upper part of the top electrode 18 and a surface of the top electrode 18.

(Manufacturing Method)

A method for manufacturing the semiconductor storage apparatus according to the second variant of the fourth embodiment includes a step of forming a source-drain diffusion layer 26 of a switching transistor on a semiconductor substrate 10 and a step of forming an interlayer insulating film 8 on the semiconductor substrate 10 and the source-drain diffusion layer 26 as shown in FIG. 16. Moreover, the method includes a step of forming a bottom electrode 14 on the interlayer insulating film 8, a step of forming the ferroelectric layer 16 on the bottom electrode 14, and a step of forming the top electrode 18 on the ferroelectric layer 16. Furthermore, the method includes a step of forming, on the top electrode 18, the hard mask 20 having a lower etching-selectivity than that of the top electrode 18, and a step of collectively processing the top electrode 18, the ferroelectric layer 16 and the bottom electrode 14 by an etching step using the hard mask 20 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 20, a second etching process using chloric gas or a fluoric gas as an etching gas may be performed as a final etching after the first etching process is performed. In the second etching process, a chemical etching performance obtained by a chemical reaction is increased more greatly than a physical etching performance.

In the same manner as in the fourth embodiment, it is possible to use SrRuO₃ or IrO₂ for the top electrode 18 of a ferroelectric capacitor, for example. It is possible to use PZT (Pb(Zr_{X}Ti_{1-X})O₃) as the ferroelectric layer 16 of the ferroelectric capacitor, for example. It is possible to use SrRuO₃, Pt, IrO₂, Ir or Ti as the bottom electrode 14 of the ferroelectric capacitor, for example.

In the same manner as in the fourth embodiment, as a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiOₓ), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

As shown in FIG. 14, on a condition that the hard mask 20 has a sharp shape, furthermore, a bias of a final etching condition is reduced and a chemical etching effect is utilized. Consequently, it is possible to obtain such a shape that an upper part of the hard mask 20 is rounded as shown in FIG. 15.

By forming the hard mask 20 to be relatively thin, furthermore, it is possible to obtain a shape in which a shoulder drop of the top electrode portion is generated, and furthermore, the hard mask 20 is completely removed as shown in FIG. 16.

As shown in FIG. 16, furthermore, it is possible to obtain the sidewall portion of the upper part of the top electrode 18 which has a round shape by reducing a bias of the etching condition and utilizing a chemical etching effect.

In the semiconductor storage apparatus according to the second variant of the fourth embodiment, as shown in FIG. 16, the sidewall portion of the upper part of the top electrode 18 is caused to have the roundness, and the top electrode 18 is separated from a leakage portion L of the sidewall portion of the ferroelectric capacitor so that a leakage is prevented.

According to the semiconductor storage apparatus having a 1-Mask-FeRAM capacitor structure and the method for manufacturing the semiconductor storage apparatus shown in each of the fourth embodiment, the first variant and the second variant, it is possible to relieve a damage of a sidewall portion and to reduce a capacitor leakage.

(Memory Cell Array)

The semiconductor storage apparatus cell according to each of the first to fourth embodiments is particularly applied to a “TC unit” series connection type chain ferroelectric memory (a chain FeRAM) in which a plurality of memory cells having both electrodes of a ferroelectric capacitor connected to source/drain regions of an MOS transistor respectively is connected in series or a 1-transistor 1-capacitor type ferroelectric memory (a 1T1C type FeRAM).

—TC Unit Series Connection Type—

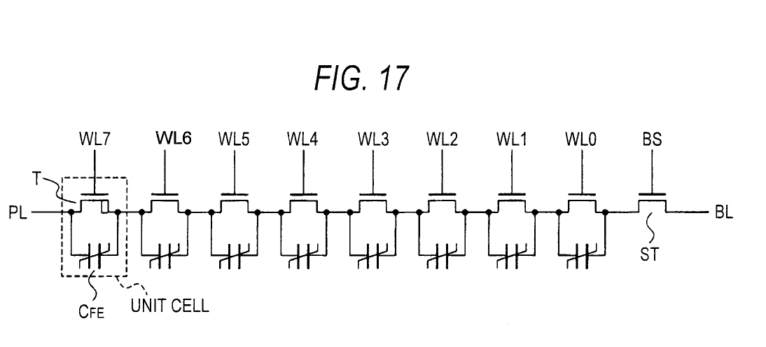

A unit cell of a TC unit series connection type FeRAM has such a structure that both ends of a ferroelectric capacitor C_{FE} are connected between a source and a drain of a cell transistor T as shown in FIG. 17, for example. A plurality of unit cells is disposed in series between a plate line PL and a bit line BL as shown in FIG. 17. A block of a TC unit series connection time FeRAM string in which the unit cells are connected in series is selected by a block selecting transistor ST. A word line WL (WL0 to WL7) is connected to a gate of each of the cell transistors T, and a block selecting line BS is connected to a gate of the block selecting transistor ST.

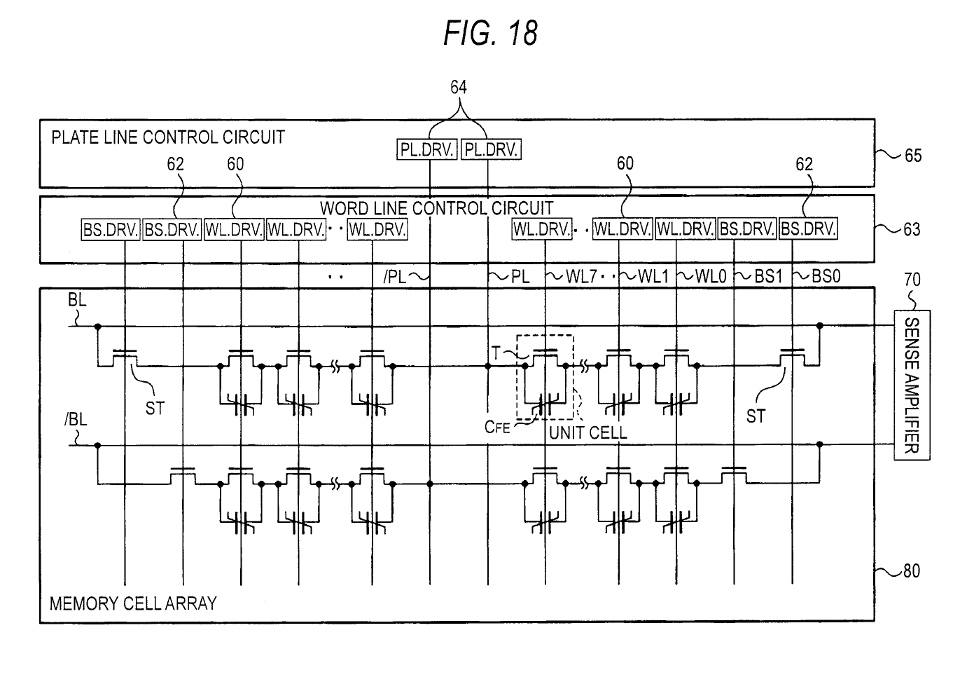

An example of a memory cell array capable of applying the ferroelectric memory cell according to each of the first to fourth embodiments has a structure of a TC unit series connection type FeRAM cell array as shown in FIG. 18.

The TC unit series connection type FeRAM cell array includes a memory cell array 80, a word line control circuit 63 connected to the memory cell array 80, and a plate line control circuit 65 connected to the word line control circuit 63 as shown in FIG. 18. In the memory cell array 80, a plurality of TC unit series connection type FeRAM cells is arranged in a matrix as shown in FIG. 18.

As shown in FIG. 18, the word lines WL (WL0 to WL7) are connected to a word line driver (WL. DRV.) 60 disposed in the word line control circuit 63 respectively, and the block selecting lines BS (BS0, BS1) are connected to a block selecting line driver (BS. DRV.) 62 disposed in the word line control circuit 63 respectively. On the other hand, the plate lines PL (PL, /PL) are connected to a plate line driver (PL. DRV.) 64 disposed in the plate line control circuit 65, respectively.

The memory cell array 80 has such a structure that the TC unit series connection type FeRAM blocks are disposed in parallel with each other in a direction in which the word line WL (WL0 to WL7) is extended. Moreover, the memory cell array 80 has such a structure that the TC unit series connection type FeRAM block is folded back around the plate line PL (PL, /PL) in a direction in which the bit line BL (BL, /BL) is extended as shown in FIG. 18.

In the TC unit series connection type FeRAM, an electric potential of the word line WL (WL0 to WL7) and that of the block selecting line BS (BS0, BS1) have an internal power VPP or a ground potential GND, for example, 0 V. In a standby state, moreover, V(WL)=VPP and V(BS)=0 V are obtained, for example. An electric potential of the plate line PL (PL, /PL) has an internal power VINT or the ground potential GND. Furthermore, V(PL)=0 V is obtained in the standby state. A sense amplifier 70 is connected to the bit line BL (BL, /BL), and a signal fixed to a high level/low level through a differential amplification is read from the FeRAM cell. In the standby state, V(BL)=0 V is set.

—1-Transistor 1-Capacitor Type—

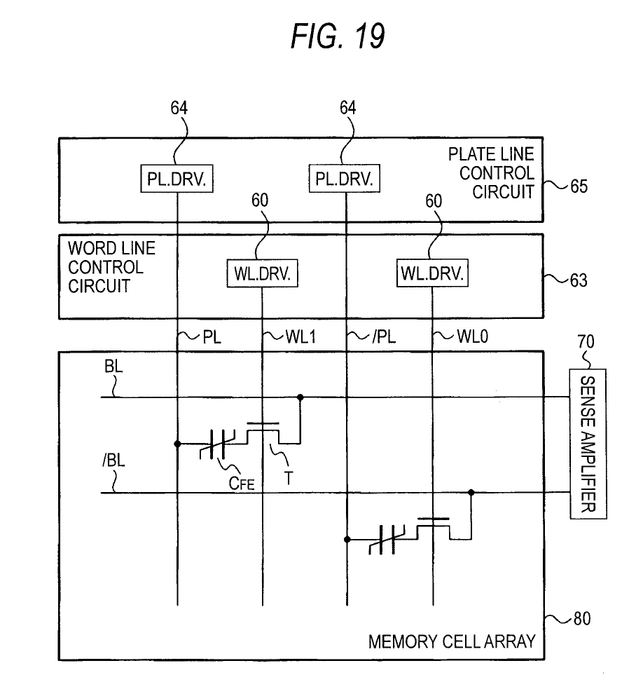

An example of other memory cell arrays capable of applying the ferroelectric memory cell according to each of the first to fourth embodiments has a structure of a 1T1C type FeRAM as shown in FIG. 19.

The 1T1C type FeRAM includes a memory cell array 80, a word line control circuit 63 connected to the memory cell array 80, and a plate line control circuit 65 connected to the word line control circuit 63 as shown in FIG. 19. A plurality of 1T1C type FeRAM cells is integrated in the memory cell array 80.

A 1T1C type FeRAM unit cell has a structure in which a ferroelectric capacitor C_{FE} is connected to a source of a cell transistor T in series as shown in FIG. 19, for example. The unit cell is disposed in an intersecting portion of a plurality of plate lines PL (PL, /PL) and a plurality of bit lines BL (BL, /BL) to constitute a matrix as shown in FIG. 19.

A word line WL is connected to a gate of each of the cell transistors T, and the other electrode on an opposite side to an electrode of the ferroelectric capacitor C_{FE} connected to a source of the cell transistor T is connected to the plate line PL (PL, /PL) as shown in FIG. 19 and the bit line BL (BL, /BL) is connected to a drain of the cell transistor T.

As shown in FIG. 19, word lines WL (WL0, WL1, . . . ) are connected to a word line driver (WL. DRV.) 60 disposed in the word line control circuit 63, respectively. On the other hand, the plate lines PL (PL, /PL) are connected to a plate line driver (PL. DRV.) 64 disposed in the plate line control circuit 65, respectively.

In the 1T1C type FeRAM, an electric potential of the word line WL has an internal power VPP or a ground potential GND, for example, 0 V. In a standby state, moreover, V(WL)=VPP is obtained, for example. An electric potential of the plate line PL (PL, /PL) has an internal power VINT or the ground potential GND. Furthermore, V(PL)=0 V is obtained in the standby state. A sense amplifier 70 is connected to the bit line BL (BL, /BL), and a signal fixed to a high level/low level through a differential amplification is read from the 1T1C type FeRAM cell. In the standby state, V(BL)=0 V is set.

### FIFTH EMBODIMENT

A 1T type semiconductor storage apparatus having an MFIS (metal-ferroelectric-insulating layer-semiconductor) structure according to a fifth embodiment includes source-drain diffusion layers 50 and 52 of a switching transistor disposed on a semiconductor substrate 10, and a gate insulating film 56 disposed on the semiconductor substrate 10 between the source-drain diffusion layers 50 and 52. Moreover, the 1T type semiconductor storage apparatus includes a ferroelectric layer 44 disposed on the gate insulating film 56 and a top electrode 46 disposed on the ferroelectric layer 44.

A ferroelectric gate capacitor having the MFIS structure is constituted by the top electrode 46, the ferroelectric layer 44, the gate insulating film 56, and the semiconductor substrate 10 provided between the source-drain diffusion layers 50 and 52. A well may be provided on the semiconductor substrate 10, and an element may be formed on the well in some cases.

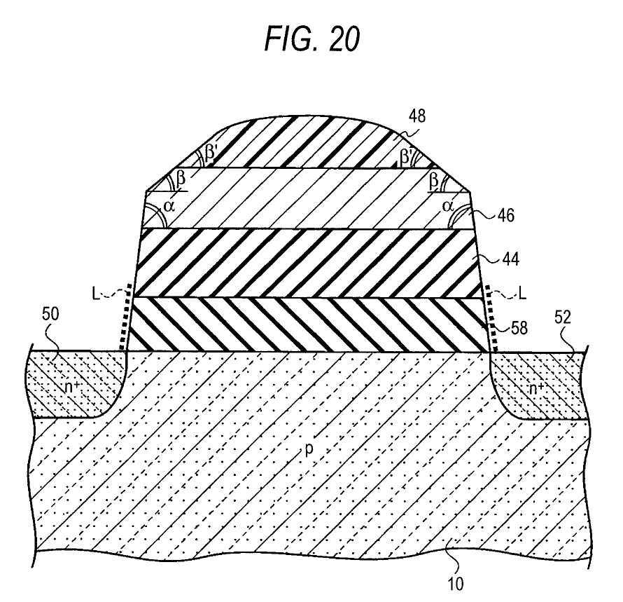

In the 1T type semiconductor storage apparatus having the MFIS structure according to the fifth embodiment, as shown in FIG. 20, an angle α formed by a sidewall portion in a position in which the top electrode 46 is provided in contact with the ferroelectric layer 44 and a surface of the ferroelectric layer 44 is larger than an angle β formed by a sidewall portion in an upper part of the top electrode 46 and the surface of the ferroelectric layer 44.

In the 1T type semiconductor storage apparatus having the MFIS structure according to the fifth embodiment, the angle β formed by the sidewall portion in the upper part of the top electrode 46 and the surface of the ferroelectric layer 44 is almost equal to an angle β′ formed by a hard mask 48 and a surface of the top electrode 46 as shown in FIG. 20.

In the 1T type semiconductor storage apparatus having the MFIS structure according to the fifth embodiment, the hard mask 48 has a semicircular sectional shape as shown in FIG. 20.

(Manufacturing Method)

A method for manufacturing the 1T type semiconductor storage apparatus having the MFIS structure according to the fifth embodiment includes a step of forming the source-drain diffusion layers 50 and 52 of a switching transistor on the semiconductor substrate 10 and a step of forming the gate insulating film 56 on the semiconductor substrate 10 and the source-drain diffusion layers 50 and 52 as shown in FIG. 20. Moreover, the method includes a step of forming the ferroelectric layer 44 on the gate insulating film 56 and a step of forming the top electrode 46 on the ferroelectric layer 44. Furthermore, the method includes a step of forming, on the top electrode 46, the hard mask 48 having a lower etching-selectivity than that of the top electrode 46, and a step of collectively processing the top electrode 46, the ferroelectric layer 44 and the gate insulating film 56 by an etching step using the hard mask 48 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 48, a second etching process using chloric gas or a fluoric gas as an etching gas is performed as a final etching after the first etching process is performed. In the second etching process, a chemical etching performance obtained by a chemical reaction is increased more greatly than a physical etching performance.

For example, the top electrode 46 is formed of SrRuO₃, IrO₂, or Pt/IrO₂/Ir/Ti, the ferroelectric layer 44 is formed of PZT (Pb(Zr_{X}Ti_{1-X})O₃), and the gate insulating film 56 is formed by a silicon oxide film.

As a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

On a condition that the hard mask 48 has a sharp shape, furthermore, a bias of a final etching condition is reduced and a chemical etching effect is utilized. Consequently, it is possible to obtain such a shape that an upper part of the hard mask 48 is rounded as shown in FIG. 20. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 48 to be relatively thin, it is possible to obtain a shape in which a shoulder drop of the top electrode portion is generated as shown in FIG. 20.

In the semiconductor storage apparatus according to the fifth embodiment, as shown in FIG. 20, the top electrode 46 is separated from a leakage portion L of the sidewall portion of the ferroelectric gate capacitor so that a leakage is prevented.

A relationship between a gate capacitor leakage current and an angle ratio β′/α in the semiconductor storage apparatus according to the fifth embodiment can be represented in the same manner as in FIG. 4.

In the semiconductor storage apparatus according to the fifth embodiment, the gate capacitor leakage current is increased if the angle α formed by a gate sidewall portion in which the top electrode 46 is provided in contact with the ferroelectric layer 44 and a surface of the ferroelectric layer 44 is equal to the angle β′ formed by the hard mask 48 and a surface of the top electrode 46.

If the angle ratio β′/α is equal to or lower than approximately 0.9, the gate capacitor leakage current is rapidly decreased.

The gate capacitor leakage current starts to be decreased when the angle ratio β′/α is decreased, that is, the angle β′ of the hard mask 48 is smaller than the angle α of the top electrode 46.

When the angle ratio β/α is slightly decreased to be approximately 0.9, the gate capacitor leakage current is reduced by approximately two digits.

The tendency becomes remarkable when the angle α formed by the sidewall portion in a position in which the top electrode 46 is provided in contact with the ferroelectric layer 44 and the surface of the ferroelectric layer 44 is equal to or larger than approximately 70 degrees.

More specifically, in the ferroelectric gate capacitor in which the angle α is equal to or larger than approximately 70 degrees, by satisfying a relationship of “the angle β′ of the hard mask 48<the angle α of the top electrode 46”, the gate capacitor leakage current can be reduced.

A relationship between the gate capacitor leakage current and the ratio (a thickness A of the hard mask 48/a thickness B of the top electrode 46) in the semiconductor storage apparatus according to the fifth embodiment can be represented in the same manner as in FIG. 5.

In the semiconductor storage apparatus according to the fifth embodiment, the gate capacitor leakage current is rapidly decreased if the ratio (the thickness A of the hard mask 48/the thickness B of the top electrode 46) is equal to or lower than approximately 1.5.

In the semiconductor storage apparatus according to the fifth embodiment, it is desirable that the thickness of the top electrode 46 should be equal to or smaller than approximately 150 nm in order to control the gate capacitor leakage current.

According to the 1T type semiconductor storage apparatus with the MFIS structure having a 1-Mask-FeRAM capacitor structure and the method for manufacturing the 1T type semiconductor storage apparatus shown in the fifth embodiment, it is possible to relieve a damage of a gate sidewall portion and to reduce a gate capacitor leakage.

### SIXTH EMBODIMENT

A 1T type semiconductor storage apparatus having an MFMIS (metal-ferroelectric-metal-insulating layer-semiconductor) structure according to a sixth embodiment includes source-drain diffusion layers 50 and 52 of a switching transistor disposed on a semiconductor substrate 10, and a gate insulating film 56 disposed on the semiconductor substrate 10 between the source-drain diffusion layers 50 and 52. Moreover, the 1T type semiconductor storage apparatus includes a bottom electrode 42 disposed on the gate insulating film 56, a ferroelectric layer 44 disposed on the bottom electrode 42 and a top electrode 46 disposed on the ferroelectric layer 44.

A ferroelectric gate capacitor having the MFMIS structure is constituted by the top electrode 46, the ferroelectric layer 44, the bottom electrode 42, the gate insulating film 56, and the semiconductor substrate 10 provided between the source-drain diffusion layers 50 and 52. A well may be provided on the semiconductor substrate 10, and an element may be formed on the well in some cases.

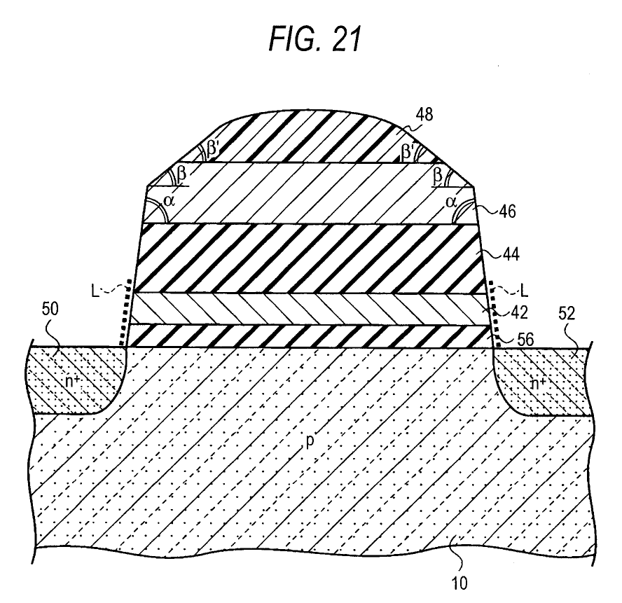

In the 1T type semiconductor storage apparatus having the MFMIS structure according to the sixth embodiment, as shown in FIG. 21, an angle α formed by a sidewall portion in a position in which the top electrode 46 is provided in contact with the ferroelectric layer 44 and a surface of the ferroelectric layer 44 is larger than an angle β formed by a sidewall portion in an upper part of the top electrode 46 and the surface of the ferroelectric layer 44.

In the 1T type semiconductor storage apparatus having the MFMIS structure according to the sixth embodiment, the angle β formed by the sidewall portion in the upper part of the top electrode 46 and the surface of the ferroelectric layer 44 is almost equal to an angle β formed by a hard mask 48 and a surface of the top electrode 46 as shown in FIG. 21.

In the 1T type semiconductor storage apparatus having the MFMIS structure according to the sixth embodiment, the hard mask 48 has a semicircular sectional shape as shown in FIG. 21.

(Manufacturing Method)

A method for manufacturing the 1T type semiconductor storage apparatus having the MFMIS structure according to the sixth embodiment includes a step of forming the source-drain diffusion layers 50 and 52 of a switching transistor on the semiconductor substrate 10 and a step of forming the gate insulating film 56 on the semiconductor substrate 10 and the source-drain diffusion layers 50 and 52 as shown in FIG. 21. Moreover, the method includes a step of forming the bottom electrode 42 on the gate insulating film 56, a step of forming the ferroelectric layer 44 on the bottom electrode 42, and a step of forming the top electrode 46 on the ferroelectric layer 44. Furthermore, the method includes a step of forming, on the top electrode 46, the hard mask 48 having a lower etching-selectivity than that of the top electrode 46, and a step of collectively processing the top electrode 46, the ferroelectric layer 44, the bottom electrode 42 and the gate insulating film 56 by an etching step using the hard mask 48 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 48, a second etching process using chloric gas or a fluoric gas as an etching gas is performed as a final etching after the first etching process is performed. In the second etching process, a chemical etching performance obtained by a chemical reaction is increased more greatly than a physical etching performance.

For the top electrode 46 of the ferroelectric gate capacitor, for example, it is possible to use SrRuO₃, IrO₂, or Pt/IrO₂/Ir/Ti. For the ferroelectric layer 44, for example, it is possible to use PZT (Pb(Zr_{X}Ti_{1-X})O₃). For the bottom electrode 42 of the ferroelectric gate capacitor, for example, it is possible to use SrRuO₃, Pt, IrO₂, Ir or Ti. The gate insulating film 56 is formed by a silicon oxide film.

As a hard mask material to be formed on the ferroelectric capacitor, for example, it is possible to use a single layer of an oxide film (SiO₂), a titanium nitride film (Ti_{X}N_{Y}), a titanium aluminum nitride film (TiAl_{X}N_{Y}), an aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

On a condition that the hard mask 48 has a sharp shape, furthermore, a bias of a final etching condition is reduced and a chemical etching effect is utilized. Consequently, it is possible to obtain such a shape that an upper part of the hard mask 48 is rounded as shown in FIG. 21. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 48 to be relatively thin, it is possible to obtain a shape in which a shoulder drop of the top electrode portion is generated as shown in FIG. 21.

In the semiconductor storage apparatus according to the sixth embodiment, as shown in FIG. 21, the top electrode 46 is separated from a leakage portion L of the sidewall portion of the ferroelectric gate capacitor so that a leakage is prevented.

A relationship between the gate capacitor leakage current and an angle ratio β′/α in the semiconductor storage apparatus according to the sixth embodiment can be represented in the same manner as in FIG. 4.

In the semiconductor storage apparatus according to the sixth embodiment, the gate capacitor leakage current is increased if the angle α formed by the gate sidewall portion in which the top electrode 46 is provided in contact with the ferroelectric layer 44 and a surface of the ferroelectric layer 44 is equal to the angle β′ formed by the hard mask 48 and the surface of the top electrode 46.

If the angle ratio β′/α is equal to or lower than approximately 0.9, the gate capacitor leakage current is rapidly decreased.

The gate capacitor leakage current starts to be decreased when the angle ratio β′/α is decreased, that is, the angle β′ of the hard mask 48 is smaller than the angle α of the top electrode 46.

When the angle ratio β′/α is slightly decreased to be approximately 0.9, the gate capacitor leakage current is reduced by approximately two digits.

The tendency becomes remarkable when the angle α formed by the sidewall portion in which the top electrode 46 is provided in contact with the ferroelectric layer 44 and the surface of the ferroelectric layer 44 is equal to or larger than approximately 70 degrees.

More specifically, in the ferroelectric gate capacitor in which the angle α is equal to or larger than approximately 70 degrees, by satisfying a relationship of “the angle β′ of the hard mask 48<the angle α of the top electrode 46”, the gate capacitor leakage current can be reduced.

A relationship between the gate capacitor leakage current and the ratio (a thickness A of the hard mask 48/a thickness B of the top electrode 46) in the semiconductor storage apparatus according to the sixth embodiment can be represented in the same manner as in FIG. 5.

In the semiconductor storage apparatus according to the sixth embodiment, the gate capacitor leakage current is rapidly decreased if the ratio (the thickness A of the hard mask 48/the thickness B of the top electrode 46) is equal to or lower than approximately 1.5.

In the semiconductor storage apparatus according to the sixth embodiment, it is desirable that the thickness of the top electrode 46 should be equal to or smaller than approximately 150 nm in order to control the gate capacitor leakage current.

According to the 1T type semiconductor storage apparatus with the MFMIS structure having a 1-Mask-FeRAM capacitor structure and the method for manufacturing the 1T type semiconductor storage apparatus shown in the sixth embodiment, it is possible to relieve a damage of a gate sidewall portion and to reduce a gate capacitor leakage.

(1-Transistor Type)

The semiconductor storage apparatus according to each of the fifth and sixth embodiments is applied to a 1-transistor type semiconductor storage apparatus (a 1T type FeRAM).

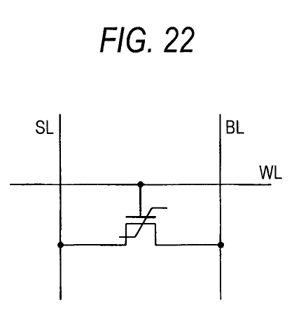

A circuit structure of a memory cell in the semiconductor storage apparatus according to each of the fifth and sixth embodiments is illustrated in FIG. 22. More specifically, a source region is connected to a source line SL, a drain region is connected to a bit line, an MOS gate capacitor structure of an MOS transistor is formed by a structure of a ferroelectric capacitor constituted by a ferroelectric material, and a word line WL is connected to an MOS gate electrode. A structure of the 1T type FeRAM shown in FIG. 22 is arranged in a matrix to constitute a memory cell array.

### SEVENTH EMBODIMENT

The collectively processing ferroelectric capacitor forming step through the 1-Mask-1-PEP for implementing the capacitor structure applied to the method for manufacturing a semiconductor storage apparatus according to each of the first to sixth embodiments can also be applied to a method for manufacturing a ferromagnetic memory (MRAM) in the same manner.

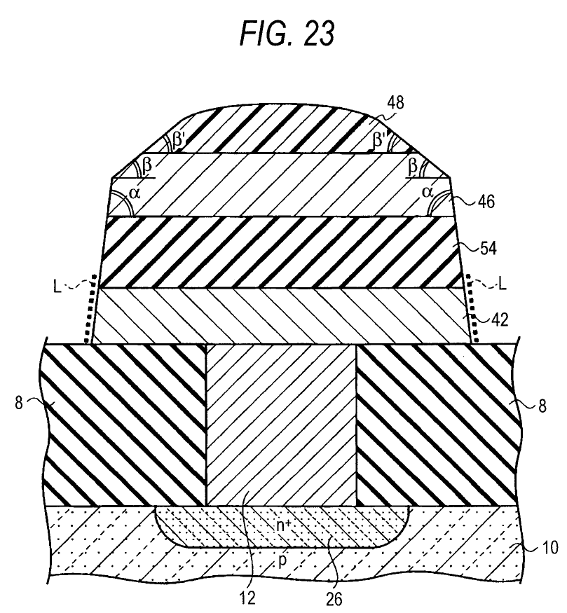

More specifically, as shown in FIG. 23, a semiconductor storage apparatus according to a seventh embodiment includes a source-drain diffusion layer 26 of a switching transistor disposed on a semiconductor substrate 10, an interlayer insulating film 8 disposed on the semiconductor substrate 10 and the source-drain diffusion layer 26, and a plug electrode 12 embedded in the interlayer insulating film 8 and disposed on the source-drain diffusion layer 26. Moreover, the semiconductor storage apparatus includes a ferromagnetic capacitor including a bottom electrode 42 disposed on the interlayer insulating film 8 and the plug electrode 12, a ferromagnetic layer 54 disposed on the bottom electrode 42, and a top electrode 46 disposed on the ferromagnetic layer 54. A well may be provided on the semiconductor substrate 10, and an element may be formed on the well in some cases.

In the semiconductor storage apparatus according to the seventh embodiment, an angle α formed by a sidewall portion in a position in which the top electrode 46 is provided in contact with the ferromagnetic layer 54 and a surface of the ferromagnetic layer 54 is larger than an angle β formed by a sidewall portion in an upper part of the top electrode 46 and the surface of the ferromagnetic layer 54.

In the semiconductor storage apparatus according to the seventh embodiment, as shown in FIG. 7, the angle α formed by the sidewall portion in the position in which the top electrode 46 is provided in contact with the ferromagnetic layer 54 and the surface of the ferromagnetic layer 54 is larger than the angle β formed by the sidewall portion in the upper part of the top electrode 46 and the surface of the ferromagnetic layer 54.

In the semiconductor storage apparatus according to the seventh embodiment, the angle β formed by the sidewall portion in the upper part of the top electrode 46 and the surface of the ferromagnetic layer 54 is almost equal to an angle β′ formed by a hard mask 48 and a surface of the top electrode 46 as shown in FIG. 23.

In the semiconductor storage apparatus according to the seventh embodiment, the hardmask 48 has a semicircular sectional shape as shown in FIG. 7.

(Manufacturing Method)

A method for manufacturing the semiconductor storage apparatus according to the seventh embodiment includes a step of forming the source-drain diffusion layer 26 of a switching transistor on the semiconductor substrate 10 and a step of forming the interlayer insulating film 8 on the semiconductor substrate 10 and the source-drain diffusion layer 26 as shown in FIG. 23. Moreover, the method includes a step of forming the bottom electrode 42 on the interlayer insulating film 8, a step of forming the ferromagnetic layer 54 on the bottom electrode 42, and a step of forming the top electrode 46 on the ferromagnetic layer 54. Furthermore, the method includes a step of forming, on the top electrode 46, the hard mask 48 having a lower etching-selectivity than that of the top electrode 46, and a step of collectively processing the top electrode 46, the ferromagnetic layer 54 and the bottom electrode 42 by an etching step using the hard mask 48 as a mask. In the etching step, a first etching process using a chloric gas or an inert gas as an etching gas is performed. In the first etching process, a physical etching performance is increased more greatly than a chemical etching performance obtained by a chemical reaction.

In the collectively processing step, to further process the hard mask 48, a second etching process using chloric gas or a fluoric gas as an etching gas is performed as a final etching after the first etching process is performed. In the second etching process, a chemical etching performance obtained by a chemical reaction is increased more greatly than a physical etching performance.

For example, the top electrode 46 is formed of IrO₂, the ferromagnetic layer 54 is formed by a ferromagnetic material constituted by Co, Co—Pt, Co—Fe, NiFe/Cu, MR-NiMnSb/Cu/NiMnSb/FeMn, or CoNiFe/Cu/Co/NiFe or CoPt/Cu/NiFeCo/Cu, and the bottom electrode 42 is formed of Pt/IrO₂/Ir/Ti.

As a hard mask material to be formed on the ferromagnetic capacitor, for example, it is possible to use a single layer of an oxide film (SiO₂), a titanium nitride film (Ti_{X}N_{Y}), a titanium aluminum nitride film (TiAl_{X}N_{Y}), an aluminum oxide film (Al_{X}O_{Y}), a silicon aluminum oxide film (SiₓAl_{y}O_{z}), a zirconium oxide film (ZrO_{X}), a titanium oxide film (TiO_{X}), a tungsten nitride film (WₓN_{y}), a tantalum nitride film (TaₓN_{y}), a titanium aluminum nitride oxide film (TiAl_{X}N_{Y}O_{Z}), and a titanium nitride oxide film (Ti_{X}N_{Y}O_{Z}) or their multilayer film.

On a condition that the hard mask 48 has a sharp shape, furthermore, a bias of a final etching condition is reduced and a chemical etching effect is utilized. Consequently, it is possible to obtain such a shape that an upper part of the hard mask 48 is rounded as shown in FIG. 23. As a specific gas for the final etching, a condition that a chloric gas (Cl₂, BCl₃) and a fluoric gas (CF₄, CHF₃, C₂F₆, C₃F₈) are utilized for main gases is suitable.

By forming the hard mask 48 to be relatively thin, it is possible to obtain a shape in which a shoulder drop of the top electrode portion is generated as shown in FIG. 23.

In the semiconductor storage apparatus according to the seventh embodiment, as shown in FIG. 23, the top electrode 46 is separated from a leakage portion L of the sidewall portion of the ferromagnetic gate capacitor so that a leakage is prevented.

A relationship between the gate capacitor leakage current and an angle ratio β′/α in the semiconductor storage apparatus according to the seventh embodiment can be represented in the same manner as in FIG. 4.

In the semiconductor storage apparatus according to the seventh embodiment, the gate capacitor leakage current is increased if the angle α formed by the gate sidewall portion in the position in which the top electrode 46 is provided in contact with the ferromagnetic layer 54 and the surface of the ferromagnetic layer 54 is equal to the angle β′ formed by the hard mask 48 and the surface of the top electrode 46.

If the angle ratio β′/α is equal to or lower than approximately 0.9, the gate capacitor leakage current is rapidly decreased.

When the angle ratio β′/α is slightly decreased to be approximately 0.9, the gate capacitor leakage current is reduced by approximately two digits.

The tendency becomes remarkable when the angle α formed by the sidewall portion in which the top electrode 46 is provided in contact with the ferromagnetic layer 54 and the surface of the ferromagnetic layer 54 is equal to or larger than approximately 70 degrees.

More specifically, in the ferromagnetic gate capacitor in which the angle α is equal to or larger than approximately 70 degrees, by satisfying a relationship of “the angle β′ of the hard mask 48<the angle α of the top electrode 46”, the gate capacitor leakage current can be reduced.

A relationship between the gate capacitor leakage current and the ratio (a thickness A of the hard mask 48/a thickness B of the top electrode 46) in the semiconductor storage apparatus according to the seventh embodiment can be represented in the same manner as in FIG. 5.

In the semiconductor storage apparatus according to the seventh embodiment, the gate capacitor leakage current is rapidly decreased if the ratio (the thickness A of the hard mask 48/the thickness B of the top electrode 46) is equal to or lower than approximately 1.5.

According to the semiconductor storage apparatus having a 1-Mask-MRAM capacitor structure and the method for manufacturing the semiconductor storage apparatus shown in the seventh embodiment, it is possible to relieve a damage of a sidewall portion and to reduce a capacitor leakage.

### OTHER EMBODIMENTS

Although the invention has been described above based on the first to seventh embodiments, it is to be understood that the invention is not restricted to the statements and drawings constituting a part of the disclosure. From the disclosure, various alternative embodiments, examples and application technologies are apparent to the skilled in the art.

Thus, it is a matter of course that the invention includes various embodiments which have not been described above.

Accordingly, the technical range of the invention is defined by only specific matters of the invention related to adequate claims from the description.

According to the semiconductor storage apparatus and the method for manufacturing the semiconductor storage apparatus in accordance with an aspect of the present invention, it is possible to relieve a damage of the sidewall portion and to reduce a capacitor leakage.

What is claimed is:

1. A semiconductor storage apparatus comprising:
a semiconductor substrate; and
a ferroelectric capacitor comprising:
a bottom electrode that is disposed above the semiconductor substrate,
a ferroelectric layer that is disposed on the bottom electrode, and
a top electrode that is disposed on the ferroelectric layer;
wherein the ferroelectric capacitor comprises:
a first sidewall portion that is located on a position where the top electrode is in contact with the ferroelectric layer, and
a second sidewall portion that is located above the first sidewall portion;
wherein the first sidewall portion forms a first angle with a top face of the ferroelectric layer;
wherein the second sidewall portion forms a second angle with the top face; and
wherein the first angle is larger than the second angle.

2. The semiconductor storage apparatus according to claim 1 further comprising:
a interlayer insulating film disposed between the semiconductor substrate and the bottom electrode.

3. The semiconductor storage apparatus according to claim 1 further comprising:
a gate insulating film that is disposed on the substrate under the bottom electrode;
a source diffusion layer that is formed in the semiconductor substrate and adjacent to the gate insulating film; and
a drain diffusion layer that is formed in the semiconductor substrate and adjacent to the gate insulating film and that is separated from the source diffusion layer.

4. The semiconductor storage apparatus according to claim 1, wherein the ferroelectric capacitor further comprises:
a third sidewall portion that is located between the first sidewall portion and the second sidewall portion; and
wherein the third sidewall portion has a curved portion.

5. The semiconductor storage apparatus according to claim 1, wherein the first angle is larger than 70 degree.

6. The semiconductor storage apparatus according to claim 1 further comprising:
a hard mask disposed on the top electrode.

7. The semiconductor storage apparatus according to claim 6, wherein the hard mask has a lower etching-selectivity than the top electrode.

8. The semiconductor storage apparatus according to claim 7, wherein the hard mask has a thickness of about A;
wherein the top electrode has a thickness of about B; and
wherein A and B satisfy 1.5≧A/B.

9. The semiconductor storage apparatus according to claim 6, wherein the hardmask comprises at least one of a silicon oxide, a titanium nitride, a titanium aluminum nitride, an aluminum oxide, a silicon aluminum oxide, a zirconium oxide, a titanium oxide, a tungsten nitride, a tantalum nitride, a titanium aluminum nitride oxide, and a titanium nitride oxide.

10. A semiconductor storage apparatus comprising:
a semiconductor substrate; and
a ferroelectric capacitor comprising:
a bottom electrode that is disposed above the semiconductor substrate,
a ferroelectric layer that is disposed on the bottom electrode, and
a top electrode that is disposed on the ferroelectric layer;
wherein the ferroelectric capacitor comprises:
a first sidewall portion that is located on a position where the ferroelectric layer is in contact with the bottom electrode, and
a second sidewall portion that is located on a position where the ferroelectric layer is in contact with the top electrode;
wherein the first sidewall portion forms a first angle with a top face of the bottom electrode;
wherein the second sidewall portion forms a second angle with the top face; and
wherein the first angle is larger than the second angle.

11. The semiconductor storage apparatus according to claim 10, wherein the ferroelectric capacitor further comprises:
a third sidewall portion that is located above the second sidewall portion;
wherein the third sidewall portion forms a third angle with the top face; and
wherein the second angle is larger than the third angle.

12. A method for manufacturing a semiconductor storage apparatus comprising:
forming a source diffusion layer and a drain diffusion layer on a semiconductor substrate;
forming an interlayer insulating film on the semiconductor substrate, on the source diffusion layer and on the drain diffusion layer;
forming a bottom electrode on the interlayer insulating film;
forming a ferroelectric layer on the bottom electrode;
forming a top electrode on the ferroelectric layer;
forming a hard mask having a lower etching-selectivity than the top electrode on the top electrode; and
collectively processing the top electrode, the ferroelectric layer and the bottom electrode by performing an etching process comprising:
a first etching process using a chloric gas or an inert gas as an etching gas.

13. The method for manufacturing a semiconductor storage apparatus according to claim 12, wherein the etching process further comprises:
a second etching process using a chloric gas or a fluoric gas as an etching gas.

14. The method for manufacturing a semiconductor storage apparatus according to claim 13, wherein the second etching process is performed after the first etching process is performed in the etching process;
wherein both of the first etching process and the second etching process are reactive ion etching process;
wherein a bias power of the second etching process is set lower than a bias power of the first etching process; and
wherein an etching pressure of the second etching process is set higher than an etching pressure of the first etching process.

15. A semiconductor storage apparatus comprising:
a semiconductor substrate; and
a ferroelectric capacitor comprising:
a bottom electrode that is disposed above the semiconductor substrate,
a ferroelectric layer that is disposed on the bottom electrode, and
a top electrode that is disposed on the ferroelectric layer;
wherein the ferroelectric capacitor comprises:
a first sidewall portion that is located on a position where the bottom electrode is in contact with the ferroelectric layer,
a second sidewall portion that is located on a position where the ferroelectric layer is in contact with the top electrode, and
a third sidewall portion that is located above the second sidewall portion;
wherein the first sidewall portion forms a first angle with a top face of the semiconductor substrate;
wherein the third sidewall portion forms a third angle with the top face; and
wherein the first angle is larger than the third angle.

16. The semiconductor storage apparatus according to claim 15, wherein the second sidewall portion forms a second angle with the top face; and
wherein the second angle is larger than the third angle.

17. The semiconductor storage apparatus according to claim 15, wherein the second sidewall portion forms a second angle with the top face; and
wherein the first angle is larger than the second angle.

18. The semiconductor storage apparatus according to claim 15, wherein the second sidewall portion forms a second angle with the top face;
wherein the first angle is larger than the second angle; and
wherein the second angle is larger than the third angle.
